(19) United States
(12) Patent Application Publication
(10) Pub. No.: US 2021/0013415 A1
(43) Pub. Date: Jan. 14, 2021

(54) VAPOR DEPOSITION MASK, FRAME-EQUIPPED VAPOR DEPOSITION MASK, VAPOR DEPOSITION MASK PREPARATION BODY, METHOD OF MANUFACTURING VAPOR DEPOSITION MASK, METHOD OF MANUFACTURING ORGANIC SEMICONDUCTOR ELEMENT, METHOD OF MANUFACTURING ORGANIC EL DISPLAY, AND METHOD OF FORMING PATTERN

(71) Applicant: Dai Nippon Printing Co., Ltd., Tokyo (JP)

(72) Inventors: Hiroshi KAWASAKI, Tokyo (JP); Katsunari OBATA, Tokyo (JP); Yasuko SONE, Tokyo (JP); Yoshinori HIROBE, Tokyo (JP)

(73) Assignee: Dai Nippon Printing Co., Ltd., Tokyo (JP)

(21) Appl. No.: 17/042,297

(22) PCT Filed: Mar. 20, 2019
(86) PCT No.: PCT/JP2019/011768

§ 371 Date: Sep. 28, 2020

(30) Foreign Application Priority Data
Apr. 19, 2018 (JP) 2018-080690

(51) Int. Cl. H01L 51/00; H01L 51/56; C23C 14/04; C23C 16/04

(52) U.S. Cl. CPC H01L 51/0011; H01L 51/001; C23C 16/042; C23C 14/042; H01L 51/56

(57) ABSTRACT

To provide a vapor deposition mask in which a metal layer is provided on a resin mask, in which the resin mask has an opening required to form a vapor deposition pattern, the resin mask contains a resin material, the metal layer contains a metal material, and provided that a glass transition temperature (Tg) of the resin material plus 100° C. is an upper limit temperature, in a linear expansion graph whose vertical axis indicates linear expansion rate and whose horizontal axis indicates temperature, an integrated value of a linear expansion curve for the resin mask over a range from a temperature of 25° C. to the upper limit temperature divided by an integrated value of a linear expansion curve for the metal layer over the range from the temperature of 25° C. to the upper limit temperature falls within a range from 0.55 to 1.45 inclusive.

### TECHNICAL FIELD

Embodiments of the present disclosure relate to a vapor deposition mask, a vapor deposition mask with a frame, a vapor deposition mask preparation body, a method of manufacturing a vapor deposition mask, a method of manufacturing an organic semiconductor element, a method of manufacturing an organic EL display, and a method of forming a pattern.

### BACKGROUND ART

Formation of a vapor deposition pattern using a vapor deposition mask is typically performed by bringing a vapor deposition mask having an opening corresponding to a pattern to be fabricated by vapor deposition and a vapor deposition target into intimate contact with each other and depositing a vapor deposition material emitted from a vapor deposition material source on the vapor deposition target through the opening.

As the vapor deposition mask used for formation of a vapor deposition pattern described above, for example, a vapor deposition mask is known that includes a resin mask having a resin mask opening corresponding to a pattern to be fabricated by vapor deposition and a metal mask having a metal mask opening (referred to also as a slit) stacked on one another (Patent Document 1, for example).

### CITATION LIST

### Patent Document

### Patent Document 1

Japanese Patent No. 5288072

### SUMMARY

### Technical Problem

A primary object of embodiments of the present disclosure is to provide a vapor deposition mask including a resin mask and a frame-equipped vapor deposition mask including the vapor deposition mask fixed to a frame that can form a more precise vapor deposition pattern, to provide a vapor deposition mask preparation body used for manufacturing the vapor deposition mask and a method of manufacturing the vapor deposition mask, and to provide a method of manufacturing an organic semiconductor element that can accurately manufacture the organic semiconductor element and a method of manufacturing an organic EL display that can accurately manufacture the organic EL display.

### Solution to Problem

A vapor deposition mask according to an embodiment of the present disclosure is a vapor deposition mask in which a metal layer is provided on a resin mask, in which the resin mask has an opening required to form a vapor deposition pattern, the resin mask contains a resin material, the metal layer contains a metal material, and provided that a glass transition temperature (Tg) of the resin material plus 100° C. is an upper limit temperature, in a linear expansion graph whose vertical axis indicates linear expansion rate and whose horizontal axis indicates temperature, an integrated value of a linear expansion curve for the resin mask over a range from a temperature of 25° C. to the upper limit temperature divided by an integrated value of a linear expansion curve for the metal layer over the range from the temperature of 25° C. to the upper limit temperature falls within a range from 0.55 to 1.45 inclusive.

The resin material may be a cured polyimide resin.

The metal material may be an iron alloy.

A frame-equipped vapor deposition mask according to an embodiment of the present disclosure includes a vapor deposition mask fixed to a frame, and incorporates the vapor deposition mask described above.

A vapor deposition mask preparation body according to an embodiment of the present disclosure is a vapor deposition mask preparation body from which a vapor deposition mask in which a metal layer is provided on a resin mask is derived, in which a metal layer is provided on a resin plate, the resin plate contains a resin material, the metal layer contains a metal material, and provided that a glass transition temperature (Tg) of the resin material plus 100° C. is an upper limit temperature, in a linear expansion graph whose vertical axis indicates linear expansion rate and whose horizontal axis indicates temperature, an integrated value of a linear expansion curve for the resin plate over a range from a temperature of 25° C. to the upper limit temperature divided by an integrated value of a linear expansion curve for the metal layer over the range from the temperature of 25° C. to the upper limit temperature falls within a range from 0.55 to 1.45 inclusive.

In the vapor deposition mask preparation body described above, the resin material may be a cured polyimide resin.

In the vapor deposition mask preparation body described above, the metal material may be an iron alloy.

A method of manufacturing a vapor deposition mask according to an embodiment of the present disclosure is a method of manufacturing a vapor deposition mask in which a metal layer is provided on a resin mask, including: a step of providing a metal layer containing a metal material on a resin plate containing a resin material; and a step of forming an opening required to form a vapor deposition pattern in the resin plate, in which the metal layer is provided on the resin plate in such a manner that, provided that a glass transition temperature (Tg) of the resin material plus 100° C. is an upper limit temperature, in a linear expansion graph whose vertical axis indicates linear expansion rate and whose horizontal axis indicates temperature, an integrated value of a linear expansion curve for the resin mask over a range from a temperature of 25° C. to the upper limit temperature divided by an integrated value of a linear expansion curve for the metal layer over the range from the temperature of 25° C. to the upper limit temperature falls within a range from 0.55 to 1.45 inclusive.

In the method of manufacturing a vapor deposition mask described above, as the resin plate, a resin plate including a cured polyimide resin may be used.

A method of manufacturing an organic semiconductor element according to an embodiment of the present disclosure uses the vapor deposition mask described above or the frame-equipped vapor deposition mask described above.

A method of manufacturing an organic EL display according to an embodiment of the present disclosure uses the organic semiconductor element manufactured in the manufacturing method described above.

A method of forming a pattern according to an embodiment of the present disclosure uses the vapor deposition mask described above or the frame-equipped vapor deposition mask described above.

### Advantageous Effects

With the vapor deposition mask or the frame-equipped vapor deposition mask according to an embodiment of the present disclosure, a vapor deposition pattern can be accurately formed. With the vapor deposition mask preparation body or the method of manufacturing a vapor deposition mask according to an embodiment of the present disclosure, a vapor deposition mask that allows precise formation of a vapor deposition pattern can be manufactured. With the method of manufacturing an organic semiconductor element, an organic semiconductor element can be accurately manufactured. With the method of manufacturing an organic EL display according to an embodiment of the present disclosure, an organic EL display can be accurately manufactured.

### BRIEF DESCRIPTION OF THE DRAWINGS

FIG. 1A is a front view of an example of a vapor deposition mask according to an embodiment of the present disclosure viewed in plan from the side of a metal layer, and FIG. 1B is a schematic cross-sectional view taken along the line A-A in FIG. 1A.

FIG. 2 shows an example of linear expansion curves for the resin mask and the metal layer.

FIG. 3 shows another example of linear expansion curves for the resin mask and the metal layer.

FIG. 4 is a front view of an example of the vapor deposition mask according to the embodiment of the present disclosure viewed in plan from the side of the metal layer.

FIG. 5 is a front view of an example of the vapor deposition mask according to the embodiment of the present disclosure viewed in plan from the side of the metal layer.

FIG. 6 is a front view of an example of the vapor deposition mask according to the embodiment of the present disclosure viewed in plan from the side of the metal layer.

FIGS. 7A and 7B are front views of examples of the vapor deposition mask according to the embodiment of the present disclosure viewed in plan from the side of the metal layer.

FIG. 8 is a front view of an example of the vapor deposition mask according to the embodiment of the present disclosure viewed in plan from the side of the metal layer.

FIG. 9 is a front view of an example of the vapor deposition mask according to the embodiment of the present disclosure viewed in plan from the side of the metal layer.

FIG. 10 is a front view of an example of a frame-equipped vapor deposition according to an embodiment of the present disclosure.

FIG. 11 is a front view of an example of the frame-equipped vapor deposition mask according to the embodiment of the present disclosure.

FIGS. 12A to 12C are front views of examples of the frame.

FIG. 13 is a schematic cross-sectional view of an example of a vapor deposition mask preparation body according to an embodiment of the present disclosure.

FIGS. 14 are diagrams showing steps of an example of a method of manufacturing a vapor deposition mask according to an embodiment of the present disclosure.

FIGS. 15 are diagrams showing examples of devices incorporating an organic EL display.

FIG. 16A is a front view of an example of the vapor deposition mask according to the embodiment of the present disclosure viewed in plan from the side of the metal layer, and FIG. 16B is a schematic cross-sectional view taken along the line A-A in FIG. 16A.

FIG. 17 is a front view of an example of the vapor deposition mask according to the embodiment of the present disclosure viewed in plan from the side of the metal layer.

FIG. 18 is a front view of an example of the vapor deposition mask according to the embodiment of the present disclosure viewed in plan from the side of the metal layer.

FIG. 19 is a front view of an example of the vapor deposition mask according to the embodiment of the present disclosure viewed in plan from the side of the metal layer.

FIG. 20 is a front view of an example of the frame-equipped vapor deposition mask according to the embodiment of the present disclosure.

FIG. 21 is a front view of an example of the frame-equipped vapor deposition mask according to the embodiment of the present disclosure.

FIG. 22 is a front view of an example of the vapor deposition mask according to the embodiment of the present disclosure viewed in plan from the side of the metal layer.

FIG. 23 is a front view of an example of the vapor deposition mask according to the embodiment of the present disclosure viewed in plan from the side of the metal layer.

FIG. 24 is a front view of an example of the vapor deposition mask according to the embodiment of the present disclosure viewed in plan from the side of the metal layer.

FIG. 25 is a front view of an example of the vapor deposition mask according to the embodiment of the present disclosure viewed in plan from the side of the metal layer.

FIG. 26 is a front view of an example of the vapor deposition mask according to the embodiment of the present disclosure viewed in plan from the side of the metal layer.

### DESCRIPTION OF EMBODIMENTS

In the following, embodiments of the present invention will be described with reference to the drawings and the like. Embodiments of the present invention can be implemented in many different forms and should not be construed as being limited to the description of the embodiments illustrated below. In the drawings, for the sake of clarification of the description, components may be exaggerated in width, thickness, shape or the like. However, these are just examples and not intended to limit the interpretation of the embodiments of the present invention. In addition, in this specification and the drawings, the same elements as those that have been described earlier with reference to another drawing already described may be denoted by the same reference symbols, and detailed descriptions thereof may be omitted as required. In addition, although terms such as above or below will be used for the sake of convenience of description, the vertical direction may be reversed. The same holds true for the horizontal direction.

<<Vapor Deposition Mask>>

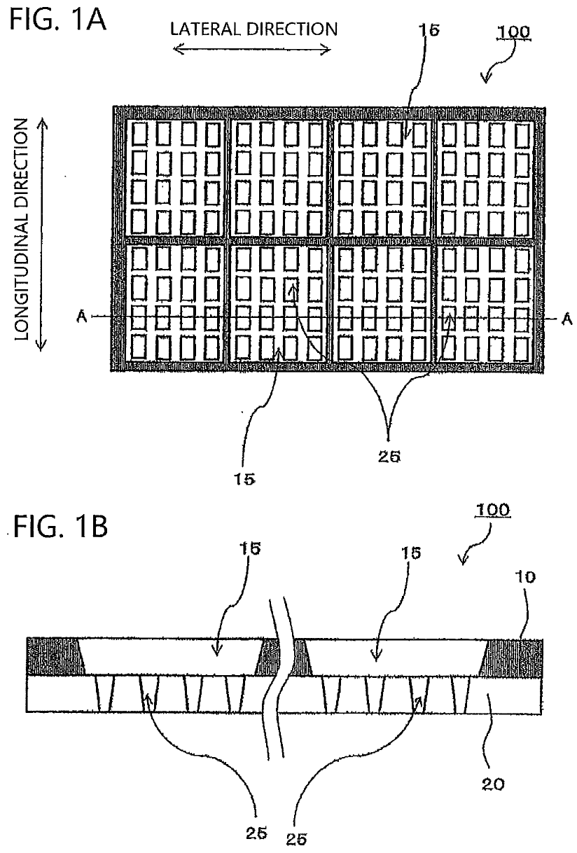

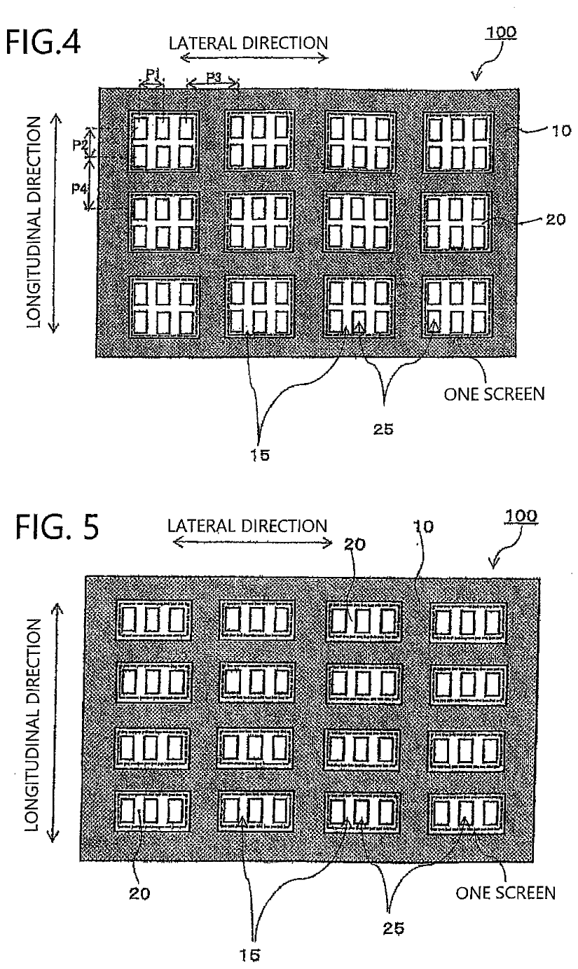

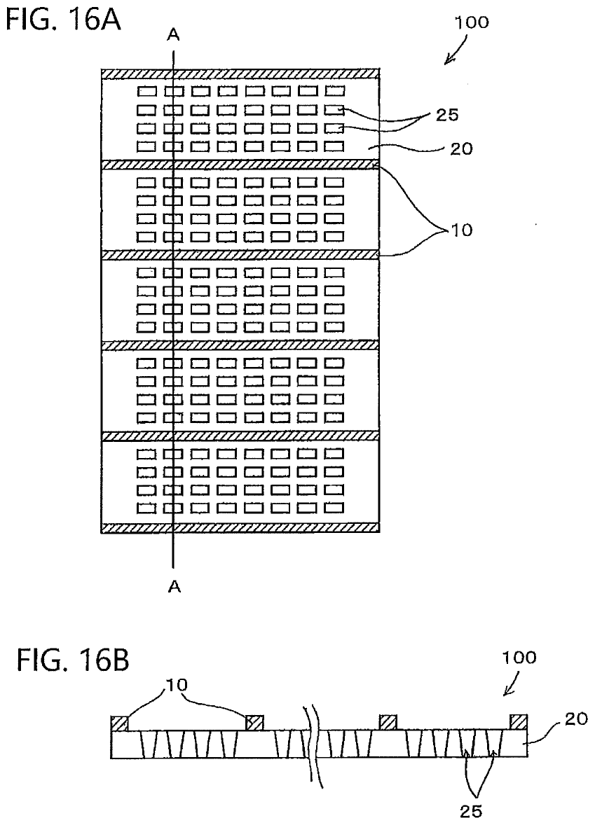

A vapor deposition mask 100 according to an embodiment of the present disclosure includes a metal layer 10 provided on a resin mask 20, and the resin mask 20 has an opening 25 required to form a vapor deposition pattern (see FIGS. 1, FIGS. 4 to 9 and FIGS. 16 to 26). The resin mask 20 contains a resin material, and the metal layer 10 contains a metal material. FIG. 1A, FIGS. 4 to 9, FIG. 16A, FIGS. 17 to 19, and FIGS. 22 to 26 are front views of vapor deposition masks 100 according to implementations of the present disclosure viewed in plan from the side of the metal layer 10, FIG. 1B is a schematic cross-sectional view taken along the line A-A in FIG. 1A, and FIG. 16B is a schematic cross-sectional view taken along the line A-A in FIG. 16A.

With a vapor deposition mask according to an embodiment of the present disclosure, in a linear expansion graph whose vertical axis indicates linear expansion rate and whose horizontal axis indicates temperature, provided that the glass transition temperature (Tg) of the resin material contained in the resin mask 20 plus 100° C. is an upper limit temperature, the integrated value of the linear expansion curve for the resin mask over a range from a temperature of 25° C. to the upper limit temperature divided by the integrated value of the linear expansion curve for the metal layer 10 over the range from the temperature of 25° C. to the upper limit temperature is defined to fall within a range from 0.55 to 1.45 inclusive.

In summary, the vapor deposition mask according to the embodiment of the present disclosure includes the metal layer 10 provided on the resin mask 20, and satisfies the following conditions.

Condition 1: the resin mask has an opening required to form a vapor deposition pattern.

Condition 2: the resin mask contains a resin material.

Condition 3: the metal layer contains a metal material.

Condition 4: in a linear expansion graph whose vertical axis indicates linear expansion rate and whose horizontal axis indicates temperature, provided that the glass transition temperature (Tg) of the resin material contained in the resin mask plus 100° C. is an upper limit temperature, the integrated value of the linear expansion curve for the resin mask over a range from a temperature of 25° C. to the upper limit temperature divided by the integrated value of the linear expansion curve for the metal layer over the range from the temperature of 25° C. to the upper limit temperature is defined to fall within a range from 0.55 to 1.45 inclusive.

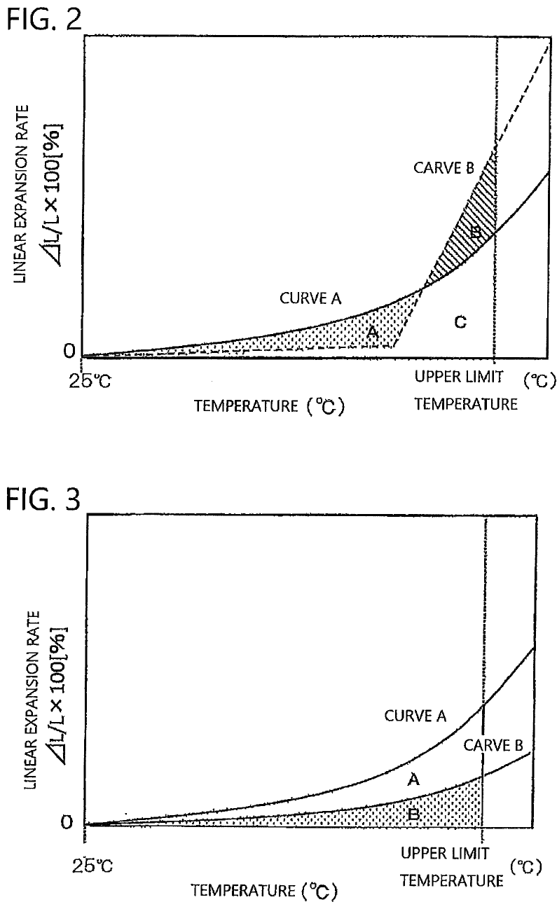

FIG. 2 is a graph whose vertical axis indicates linear expansion rate and whose horizontal axis indicates temperature, showing a relationship between the linear expansion curves for the resin mask and the metal layer. In the graph showing a relationship between the linear expansion curves in FIG. 2, one of the curves A and B is the linear expansion curve for the resin mask, and the other is the linear expansion curve for the metal layer. The linear expansion curves are not limited to the forms of the linear expansion curves shown in the drawing. For example, although the curves A and B shown in the drawing intersect with each other in the range from 25° C. to the upper limit temperature, the curves A and B may not intersect with each other in the range from 25° C. to the upper limit temperature (see FIG. 3). Alternatively, the curves A and B may intersect with each other at a temperature higher than the upper limit temperature or a temperature lower than 25° C. (not shown).

In the graph showing a relationship between the linear expansion curves in FIG. 2, if the curve A is supposed to be the linear expansion curve for the resin mask, the integrated value of the linear expansion curve for the resin mask over the range from 25° C. to the upper limit temperature is the sum of the area of a region (A region) denoted by reference symbol “A” and the area of a region (C region) denoted by reference symbol “C” in the drawing. In the graph showing a relationship between the linear expansion curves in FIG. 2, if the curve B is supposed to be the linear expansion curve for the metal layer, the integrated value of the linear expansion curve for the metal layer over the range from 25° C. to the upper limit temperature is the sum of the area of a region (B region) denoted by reference symbol “B” and the area of the region (C region) denoted by reference symbol “C” in the drawing. Therefore, in the graph showing a relationship between the linear expansion curves in FIG. 2, if the curve A is the linear expansion curve for the resin mask, and the curve B is the linear expansion curve for the metal layer, the vapor deposition mask according to the embodiment of the present disclosure satisfies the relation of the following formula (1).

0.55≤(total area of A region and C region)/(total area of B region and C region)≤1.45 Formula (1)

On the other hand, in the graph showing a relationship between the linear expansion curves in FIG. 2, if the curve B is the linear expansion curve for the resin mask, and the curve A is the linear expansion curve for the metal layer, the vapor deposition mask according to the embodiment of the present disclosure satisfies the relation of the following formula (2).

0.55≤(total area of B region and C region)/(total area of A region and C region)≤1.45 Formula (2)

In the graph showing a relationship between the linear expansion curves in FIG. 3, if the curve A is supposed to be the linear expansion curve for the resin mask, and the curve B is supposed to be the linear expansion curve for the metal layer, the integrated value of the linear expansion curve for the resin mask over the range from 25° C. to the upper limit temperature is the sum of the area of a region (A region) denoted by reference symbol “A” and the area of the region (B region) denoted by reference symbol “B” in the drawing, and the integrated value of the linear expansion curve for the metal layer is the sum of the area of the region (B region) denoted by reference symbol “B” in the drawing. Therefore, in the graph showing a relationship between the linear expansion curves in FIG. 3, if the curve A is the linear expansion curve for the resin mask, and the curve B is the linear expansion curve for the metal layer, the vapor deposition mask according to the embodiment of the present disclosure satisfies the relation of the following formula (3).

0.55≤((total area of A region and B region)/area of B region)≤1.45 Formula (3)

However, in the graph showing a relationship between the linear expansion curves in FIG. 3, if the curve A is the linear expansion curve for the resin mask, and the curve B is the linear expansion curve for the metal layer, ((total area of A region and B region)/area of B region) is greater than 1.

On the other hand, in the graph showing a relationship between the linear expansion curves in FIG. 3, if the curve B is the linear expansion curve for the resin mask, and the curve A is the linear expansion curve for the metal layer, the vapor deposition mask according to the embodiment of the present disclosure satisfies the relation of the following formula (4).

0.55≤(area of B region/(total area of A region and B region))≤1.45 Formula (4)

However, in the graph showing a relationship between the linear expansion curves in FIG. 3, if the curve B is the linear expansion curve for the resin mask, and the curve A is the linear expansion curve for the metal layer, (area of B region/(total area of A region and B region)) is smaller than 1.

(Method of Creating Linear Expansion Curve)

The vapor deposition mask is separated into the resin mask and the metal layer, which are cut to provide samples having a width of 5 mm and a length of 18 mm (a resin mask sample and a metal layer sample). The resin mask sample is obtained by removing the metal layer from the vapor deposition mask by etching. The metal layer sample is obtained by removing the resin mask from the vapor deposition mask by etching. As for the resin mask, a part that has no opening is cut. If the metal layer is small and cannot be cut into a sample having a width of 5 mm and a length of 18 mm, a metal layer that is made of the same metal material and has the same thickness as the metal layer of the vapor deposition mask is prepared, and the prepared metal layer is cut into a metal layer sample having a width of 5 mm and a length of 18 mm.

For each of the cut resin mask sample and metal layer sample, a CTE curve (linear expansion curve) with respect to 25° C. is created according to a linear expansion rate testing method in conformity with JIS-K-7197(1991). In the linear expansion rate test, the resin mask sample and the metal layer sample are held by a metal jig at the opposite edge parts thereof, which have a width of 1.5 mm, so that the actual sample length is 15 mm. The humidity the atmosphere during the measurement is controlled to be 55±2% RH.

The linear expansion rate test is performed twice for each sample. The CTE curve (linear expansion curve) with respect to 25° C. is created based on the second measurement data, which is obtained after the operation of the testing device and the condition of the sample have sufficiently settled down.

In this way, a CTE curve from 25° C. to a predetermined temperature is obtained.

The device used is TMA (EXSTAR6000, Seiko Instruments Inc.).

The vertical axis of the graph of the CTE curve indicates linear expansion rate, which is calculated as ΔL/L×100 (ΔL is the sample length at an arbitrary temperature minus the sample length at 25° C., and L is the sample length at 25° C.). That is, the linear expansion rate (%) at 25° C. is 0.

(Calculation of Integrated Value)

For each of the resin mask sample and the metal layer sample, the integrated value of the CTE curve over the region from 25° C. to the upper limit temperature is calculated, and the ratio between the integrated values for the resin mask sample and the metal layer sample is determined by dividing the integrated value for the CTE curve of the resin mask sample by the integrated value for the CTE curve of the metal layer sample. The vapor deposition mask according to the embodiment of the present disclosure satisfies a condition that the ratio determined in this manner falls within a range from 0.55 to 1.45 inclusive.

The glass transition temperature (Tg) referred to in this specification means a temperature that is defined in JIS-K-7121 (2012) and is determined by measurement of a variation in calorie by differential scanning calorimetry (DSC) (DSC method).

The resin mask 20 may contain only one kind of resin material or contain two or more kinds of resin materials. When the resin mask 20 contains two or more kinds of resin materials, the highest glass transition temperature (Tg) of the glass transition temperatures (Tg) of the resin materials detected by DSC (differential scanning calorimetry) is used for prescribing the upper limit temperature.

With the vapor deposition mask according to the embodiment of the present disclosure that satisfies the conditions 1 to 4 described above, in particular, the condition 4 described above, occurrence of a variation in dimension or position of the opening 25 formed in the resin mask 20 can be inhibited. Therefore, with the vapor deposition mask according to the embodiment of the present disclosure, a vapor deposition pattern can be accurately formed.

More specifically, by configuring the vapor deposition mask so as to satisfy the condition 4 described above, the difference in amount of shrinkage between the resin mask 20 and the metal layer 10 can be reduced. This allows occurrence of a variation in dimension or position of the opening 25 formed in the resin mask 20 to be inhibited.

For example, when the resin mask 20 having the opening 25 is obtained by applying a coating liquid containing a resin material that is cured by heat, heating the coating liquid at a temperature higher than the setting temperature of the resin material, and forming the opening 25 in the resulting resin plate (resin layer), if the resin material is selected so that the integrated value for the linear expansion curve of the resin mask over the range from 25° C. to the upper limit temperature divided by the integrated value for the linear expansion curve of the metal layer 10 over the range from 25° C. to the upper limit temperature falls within the range from 0.55 to 1.45 inclusive, the amount of shrinkage of the resin mask when the temperature is lowered from the temperature higher than the setting temperature to almost room temperature can be brought close to the amount of shrinkage of the metal layer 10. By reducing the difference in amount of shrinkage between the resin mask and the metal layer 10, the difference in internal stress between the resin mask 20 and the metal layer 10 can be reduced. This allows occurrence of a variation in dimension or position of the opening 25 in the resin mask 20 to be inhibited.

When the conditions 1 to 3 are satisfied but the condition 4 described above is not satisfied, in particular, when the integrated value for the linear expansion curve of the resin mask over the range from 25° C. to the upper limit temperature divided by the integrated value for the linear expansion curve of the metal layer over the range from 25° C. to the upper limit temperature is smaller than 0.55, the resin mask 20 slackens, or in other words, the resin mask 20 becomes creased, and such slack or creases tend to cause a variation in dimension, position or the like of the opening 25 formed in the resin mask 20. On the other hand, when the integrated value for the linear expansion curve of the resin mask over the range from 25° C. to the upper limit temperature divided by the integrated value for the linear expansion curve of the metal layer over the range from 25° C. to the upper limit temperature is greater than 1.45, an excessive tension is applied to the resin mask 20, or in other words, the resin mask 20 is pulled, and a variation in dimension, position or the like of the opening 25 formed in the resin mask 20 is likely to occur. Such slack or creases of the resin mask or the excessive tension on the resin mask can occur in various situations in which the vapor deposition mask is used. For example, when a vapor deposition pattern is formed with the vapor deposition mask, a variation in dimension or position of the opening 25 can occur.

A reason why the integrated values for the linear expansion curves for the resin mask and the metal layer are calculated over the range from 25° C. to the upper limit temperature (the glass transition temperature (Tg) of the resin material plus 100° C.) is that, even though the integrated value for the linear expansion curve of the resin mask over the range from 25° C. to the glass transition temperature (Tg) of the resin material divided by the integrated value for the linear expansion curve of the metal layer 10 over the range from 25° C. to the glass transition temperature (Tg) of the resin material falls within the range from 0.55 to 1.45 inclusive, if the integrated value for the linear expansion curve of the resin mask over the range from 25° C. to the upper limit temperature divided by the integrated value for the linear expansion curve of the metal layer 10 over the range from 25° C. to the upper limit temperature does not fall within the range from 0.55 to 1.45 inclusive, occurrence of a variation in dimension, position or the like of the opening 25 formed in the resin mask 20 or occurrence of creases of the resin mask cannot be sufficiently inhibited.

In order to further inhibit occurrence of creases or a variation in dimension of position of the opening 25, the integrated value for the linear expansion curve of the resin mask over the range from 25° C. to the upper limit temperature divided by the integrated value for the linear expansion curve of the metal layer 10 over the range from 25° C. to the upper limit temperature preferably falls within a range from 0.75 to 1.25 inclusive.

The resin material contained in the resin mask and the metal material contained in the metal layer are not particularly limited, and any material that satisfies the condition 4 described above can be appropriately chosen. Examples of the metal material include stainless steel, iron-nickel alloy, aluminum alloy. The metal layer may contain only one kind of metal material or contain two or more kinds of metal materials.

Among others, iron alloy is preferably used as the metal material contained in the metal layer, because the iron alloy is less susceptible to heat deformation. The iron alloy may be Fe—36Ni alloy (invar), Fe—32Ni—5Co alloy, or Fe—29Ni—17Co alloy, for example. When selecting the resin material to be contained in the resin mask, the resin material to be contained in the resin mask can be selected by considering the compatibility between the resin material and the iron alloy that is preferred as the metal material to be contained in the metal layer so that the condition 4 described above is satisfied.

As the metal layer, a metal plate (which may be a metal steel plate, a metal foil, a metal layer or the like) obtained by rolling and plating can also be used. Alternatively, a metal plate obtained by physical vapor deposition, such as reactive sputtering, vacuum deposition, ion plating or electron beam deposition, or chemical vapor deposition, such as thermal CVD, plasma CVD or photo CVD, can also be used. The metal layer 10 may be the metal plate obtained in any of the various processes described above as it is, or may be the metal plate processed. The metal layer may have a single-layer structure or a multi-layer structure including two or more layers stacked on one another. For example, when the metal layer 10 is formed by plating, the metal layer 10 may have a multi-layer structure including a metal layer formed by electroless plating and a metal layer formed by electroplating stacked on one another (in any order), or may have a single-layer structure formed by any one of electroless plating and electroplating.

The resin material contained in the resin mask can be determined to satisfy the condition 4 described above by considering the compatibility with the metal layer and is not limited to any particular resin material. For example, the resin material may be polyimide resin, polyamide resin, polyamide-imide resin, epoxy resin, melamine resin, urea resin, unsaturated polyester resin, diallyl phthalate resin, polyurethane resin, silicone resin, acrylic resin, polyvinyl acetal resin, polyester resin, polyethylene resin, polyvinyl alcohol resin, polypropylene resin, polycarbonate resin, polystyrene resin, polyacrylonitrile resin, ethylene-vinyl acetate copolymer, ethylene-vinyl alcohol copolymer, ethylene-methacrylate copolymer, polyvinyl chloride resin, polyvinylidene chloride resin, cellophane, or ionomer resin. The resin material may be a thermoplastic resin or a cured thermosetting resin. Among others, a resin mask 20 containing a cured polyimide resin is particularly preferable because of the high accuracy of dimensions and the small variation in position of the opening 25 in the resin mask 20, provided that the conditions 1 to 4 described above are satisfied.

Next, the resin mask 20 and the metal layer 10 forming the vapor deposition mask according to the embodiment of the present disclosure will be described with regard to examples.

<Resin Mask>

As shown in FIG. 1A, FIGS. 4 to 9, FIG. 16A, and FIGS. 17 to 26, the resin mask 20 has the opening 25 required to form a vapor deposition pattern. The resin mask 20 may have an opening (hole) different from the opening 25 required to form a vapor deposition pattern (although not shown). In the embodiment illustrated, the opening 25 has a rectangular shape. However, the shape of the opening 25 is not particularly limited, and the opening 25 can have any shape that corresponds to the pattern to be formed by vapor deposition. For example, the opening 25 may have a rhombic shape or other polygonal shape, or a shape having a curvature, such as a circular or elliptical shape. The rectangular or other polygonal shape is a preferable shape of the opening 25, because such shapes provide larger luminescent areas than shapes having a curvature, such as a circular or elliptical shape.

Although the thickness of the resin mask 20 is not particularly limited, the thickness of the resin mask 20 is preferably equal to or less than 25 μm, or more preferably less than 10 μm, from the viewpoint of inhibiting a shadow. Although there is no preferable range of the lower limit value of the thickness, if the thickness of the resin mask 20 is less than 3 μm, a defect, such as a pin hole, tends to occur, and the risk of deformation or the like increases. In particular, if the thickness of the resin mask 20 is equal to or greater than 3 μm and smaller than 10 μm, or more preferably, equal to or greater than 4 μm and equal to or smaller than 8 μm, the influence of a shadow can be more effectively prevented when a pattern is formed with a resolution higher than 400 ppi. The resin mask 20 and the metal layer 10 described later may be directly bonded to each other or may be bonded with an adhesive layer interposed therebetween. When the resin mask 20 and the metal layer 10 are bonded with an adhesive layer interposed therebetween, the overall thickness of the resin mask 20 and the adhesive layer preferably falls within the preferably thickness range described above. Note that the “shadow” refers to a phenomenon in which some of the vapor deposition material emitted from the vapor deposition material source collides with a cut face of the metal layer 10 or an inner wall face of the opening in the resin mask and therefore fails to reach the vapor deposition target, and therefore a non-deposited part having a deposition thickness smaller than an intended deposition thickness occurs.

The cross-sectional shape of the opening 25 is also not particularly limited. The opposite edge faces of the opening 25 in the resin mask may be substantially parallel to each other. However, as shown in FIG. 1B, the opening 25 preferably has a cross-sectional shape with opposite edge faces thereof being inclined so that the opening 25 expands as it goes toward the metal layer 10. The inclination can be appropriately determined by considering the thickness of the resin mask 20 or the like. However, in the cross section taken along the direction of height of the inner wall face of the opening 25 in the resin mask 20, the angle formed by the inner wall face of the opening 25 and the face of the resin mask 20 farther from the metal layer 10 (the upper face of the resin mask in the drawing) preferably falls within a range from 5° to 85° inclusive, more preferably falls within a range from 15° to 75° inclusive, and still more preferably falls within a range from 25° to 65° inclusive. Among these ranges, in particular, the angle is preferably smaller than the vapor deposition angle of the vapor deposition machine used. Although the edge faces defining the opening 25 are straight in the illustrated embodiment, embodiments of the present invention are not limited thereto. The edge faces of the opening 25 may be outwardly curved, that is, the opening 25 may have a bowl-like shape as a whole.

<Metal Layer>

As shown in FIGS. 1, FIGS. 4 to 9 and FIGS. 16 to 26, the metal layer 10 is provided on one face of the resin mask 20. The metal layer 10 is a layer containing a metal material. The metal layer 10 may be directly provided on the resin mask 20 or may be provided on the resin mask 20 with another structure interposed therebetween. Note that a structure including the metal layer 10 directly provided on the resin mask 20 is preferable because a variation in dimension or position of the opening 25 that can occur in the resin mask 20 or creases that can occur in the resin mask can be more effectively inhibited.

With the vapor deposition mask 100 shown in FIGS. 1 and FIGS. 4 to 9, the resin mask 20 has a plurality of openings 25, and the metal layer 10 is provided on the resin mask 20 to surround the openings 25 of the resin mask 20. In other words, with the vapor deposition mask 100 shown in FIGS. 1 and FIGS. 4 to 9, the metal layer 10 has one or more through-holes 15, and at least one of the through-holes 15 overlaps with one or more of the openings 25 of the resin mask 20. The through-hole 15 of the metal layer 10 is synonymous with the opening of the metal layer 10. The through-hole 15 of the metal layer 10 can be referred to also as an opening of a metal mask.

With the vapor deposition mask 100 shown in FIGS. 16 to 26, the resin mask 20 has a plurality of openings 25, and the metal layer 10 is located on parts of the resin mask 20. The vapor deposition masks shown in the drawings will be described later.

The ratio of the area of the metal layer 10 overlapping with the resin mask 20 to the area of the face of the resin mask 20 closer to the metal layer 10 (which does not include the area of the inner wall face of the opening) is not particularly limited, and can be any value as far as the metal layer 10 is provided on the resin mask 20 and the conditions 1 to 4 described above are satisfied. Note that the ratio of the metal layer 10 overlapping with the resin mask is calculated with respect to the area of the face of the metal layer 10 closer to the resin mask. Note that the “metal layer 10 overlapping with the resin mask” does not mean only the metal layer 10 that is in direct contact with the resin mask but also mean the metal layer 10 that overlaps with the resin mask 20 without a direct contact.

For example, comparing vapor deposition masks that have the same ratio of the area of the metal layer 10 overlapping with the resin mask 20 to the area of the face of the resin mask 20 closer to the metal layer 10 and differ in whether to satisfy the condition 4 described above, the vapor deposition mask that satisfies the condition 4 described above has a smaller difference in internal stress between the resin mask 20 and the metal layer 10 and is superior in inhibition of a variation in dimension or position of the opening 25 that can occur in the resin mask 20, regardless of the ratio of the area of the metal layer 10.

With the preferable vapor deposition mask 100 according to the present disclosure, the ratio of the area of the face of the metal layer 10 overlapping with the resin mask 20 to the area of the face of the resin mask 20 closer to the metal layer 10 (referred to as the ratio of the metal layer, hereinafter) is as follows.

(1) Implementation in Which the Metal Layer 10 has a Plurality of Through-Holes 15 (see FIGS. 1 and FIGS. 4 to 7)

The ratio of the metal layer 10 according to this implementation preferably equal to or higher than 20% and equal to or lower than 70%, and more preferably equal to or higher than 25% and equal to or lower than 65%.

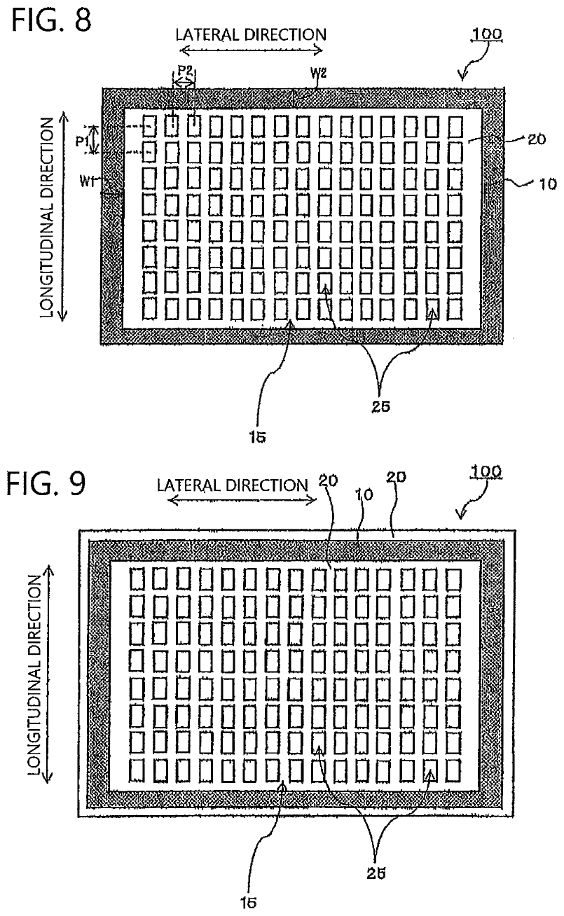

(2) Implementation in Which the Metal Layer 10 has One Through-Hole 15 (See FIGS. 8 and 9)

The ratio of the metal layer 10 according to this implementation preferably equal to or higher than 5% and equal to or lower than 40%, and more preferably equal to or higher than 10% and equal to or lower than 30%.

(3) Implementation in Which a Plurality of Metal Layers 10 is Provided on Parts of the Resin Mask 20 (See FIGS. 16 to 26)

The ratio of the metal layer 10 according to this implementation preferably equal to or higher than 0.5% and equal to or lower than 50%, and more preferably equal to or higher than 5% and equal to or lower than 40%.

By setting the ratio of the metal layer 10 to fall within the preferable range described above, the accuracy of the dimensions of the opening 25 of the resin mask 20 can be increased, and the variation in position of the opening 25 can be reduced.

In the following, arrangements of the metal layer 10 will be described with reference to vapor deposition masks according to first to third implementations. Note that the vapor deposition masks 100 according to the implementations described below satisfy the conditions 1 to 4 described above. Therefore, occurrence of a variation in dimension or position of the opening 25 in the resin mask 20 can be inhibited. A precise vapor deposition pattern can be formed with these vapor deposition masks.

(Vapor Deposition Mask According to First Implementation)

As shown in FIGS. 1 and FIGS. 4 to 7, the vapor deposition mask 100 according to the first implementation is a vapor deposition mask for forming vapor deposition patterns for a plurality of screens at the same time. The metal layer 10 is located on one face of the resin mask 20, a plurality of “screens” of openings 25 is formed in the resin mask 20, and the metal layer 10 has a plurality of through-holes 15 that overlaps with at least one screen in the resin mask 20.

According to the vapor deposition mask 100 of the first implementation, vapor deposition patterns for a plurality of products can be formed at the same time with one vapor deposition mask 100. The “opening” in the vapor deposition mask referred to in this specification means an opening required to form a vapor deposition pattern. In other words, the “opening” means a pattern to be fabricated with the vapor deposition mask 100. For example, if the vapor deposition mask is used to form an organic layer of an organic EL display, the shape of the opening corresponds to the shape of the organic layer. Furthermore, the “screen” refers to a set of openings 25 for one product. If the product is an organic EL display, the “screen” is a set of organic layers required for one organic EL display. That is, the “screen” refers to a set of openings 25 to form the organic layers of one organic EL display. In the vapor deposition mask 100 according to the first implementation, in order to form vapor deposition patterns including a plurality of screens at the same time, a plurality of “screens” is arranged at a predetermined distance in the resin mask 20. That is, the resin mask 20 has a plurality of screens of openings 25 formed therein.

In the vapor deposition mask 100 shown in FIG. 4, the metal layer 10 having a plurality of through-holes 15 is provided on one face of the resin mask, and two or more through-holes 15 in the metal layer are each arranged to overlap with the whole of one screen in the resin mask 20. The vapor deposition mask 100 according to the first implementation is a vapor deposition mask in which there is no metal layer 10 between adjacent openings 25 in the lateral direction in a screen of openings 25.

With the vapor deposition mask 100 according to the first implementation, even if the size of the openings 25 in a screen or the pitch of the openings 25 in a screen is reduced, for example, even if the size of the openings 25 or the pitch of the openings 25 is extremely small in order to form a screen having a resolution higher than 400 ppi, an interference from the metal layer 10 can be prevented, and a precise image can be formed. Note that if there is the metal layer 10 between the openings 25 in a screen, as the pitch of the openings 25 in one screen decreases, the metal layer between the openings 25 comes to interfere with the formation of the vapor deposition pattern on the vapor deposition target, and it becomes difficult to accurately form a vapor deposition pattern. In other words, if there is the metal layer 10 between the openings 25 in a screen, once the vapor deposition mask is provided with a frame, the metal layer 10 causes a shadow and makes it difficult to form a precise screen.

Next, with reference to FIGS. 4 to 7, examples of openings 25 forming a screen will be described. Note that, in these drawings, each region enclosed by a dashed line is one screen. In the drawings, each screen is a set of a small number of openings 25 for the convenience of explanation. However, the embodiments of the present invention are not limited to such implementations, and provided that one opening 25 provides one pixel, one screen may include several millions of pixels (openings 25).

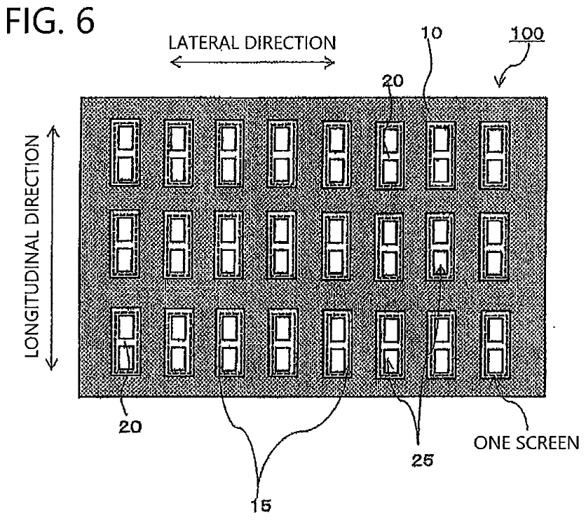

In FIG. 4, one screen includes a set of openings 25 in which a plurality of openings 25 is arranged in the longitudinal direction and the lateral direction. In FIG. 5, one screen includes a set of openings 25 in which a plurality of openings 25 is arranged in the lateral direction. In FIG. 6, one screen includes a set of openings 25 in which a plurality of openings 25 is arranged in the longitudinal direction. In FIGS. 4 to 7, a through-hole 15 in the metal layer is located to overlap with the whole of a screen.

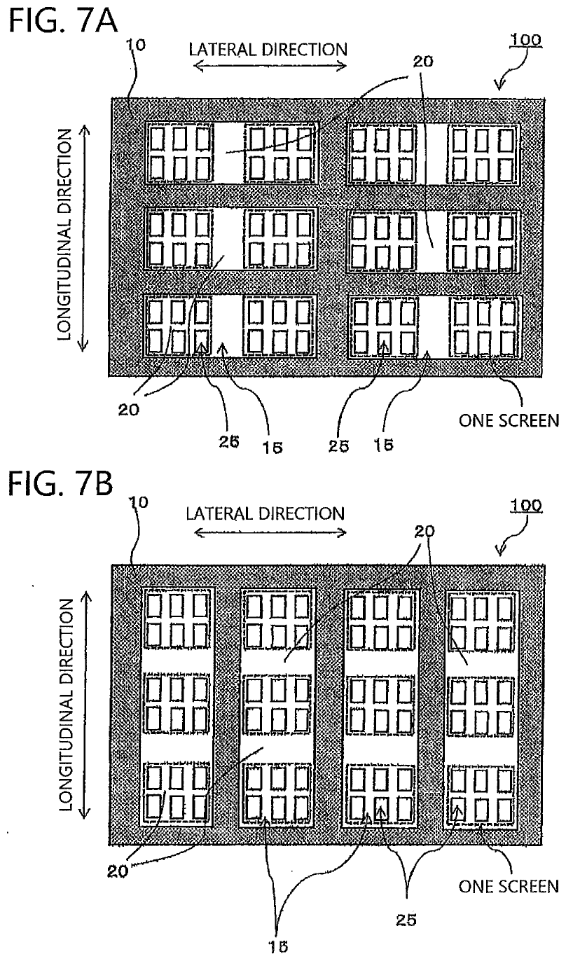

As described above, the through-hole 15 in the metal layer may be located to overlap with only one screen or located to overlap with the whole of two or more screens as shown in FIGS. 7A and 7B. In FIG. 7A, in the vapor deposition mask 100 shown in FIG. 4, the through-hole 15 in the metal layer is located to overlap with the whole of two screens that are consecutive in the lateral direction. In FIG. 7B, the through-hole 15 in the metal layer is located to overlap with the whole of three screens that are consecutive in the longitudinal direction.

Next, with reference to the configuration shown in FIG. 4, the pitch of the openings 25 forming one screen and the pitch of the screens will be described. The pitch of the openings 25 forming one screen and the size of the openings 25 are not particularly limited and can be appropriately determined for each particular pattern to be fabricated by vapor deposition. For example, when accurately forming a vapor deposition pattern having a resolution higher than 400 ppi, a lateral pitch (P1) and a longitudinal pitch (P2) of adjacent openings 25 in the openings 25 forming one screen are 60 pm. As an example, the size of the openings falls within a range from 500 μm² to 1000 μm² inclusive. One opening 25 does not necessarily correspond to one pixel. For example, depending on the arrangement of pixels, one opening 25 may correspond to a set of a plurality of pixels.

A lateral pitch (P3) and a longitudinal pitch (P4) of screens are also not particularly limited. However, when each through-hole 15 in the metal layer is located to overlap with the whole of one screen as shown in FIG. 4, the metal layer 10 exists between the screens. Therefore, if the longitudinal pitch (P4) and the lateral pitch (P3) of the screens are smaller than or substantially the same as the longitudinal pitch (P2) and the lateral pitch (P1) of the openings 25 in one screen, respectively, the metal layer 10 between the screens is susceptible to breakage. In this respect, the pitches (P3, P4) of the screens are preferably wider than the pitches (P1, P2) of the openings 25 forming one screen. For example, the pitches (P3, P4) of the screens fall within a range from lmm to 100 mm inclusive. The “pitch of the screens” means the distance between an opening in a screen and an opening adjacent to the opening in another screen adjacent to the screen. The same holds true for the pitches of the openings 25 and the pitches of the screens of the vapor deposition masks according to other implementations described later.

Note that, if one through-hole 15 in the metal layer is located to overlap with the whole of two or more screens as shown in FIGS. 7, the metal layer 10 does not exist between the screens that overlap with the same through-hole 15 in the metal layer. In this case, the pitch of the two or more screens that overlap with the same through-hole 15 in the metal layer can be substantially the same as the pitch of the openings 25 forming one screen.

<Vapor Deposition Mask According to Second Implementation>

Next, a vapor deposition mask according to a second implementation will be described. As shown in FIGS. 8 and 9, in the vapor deposition mask according to the second implementation, a metal layer 10 having one through-hole 15 is provided on one face of a resin mask 20 in which a plurality of openings 25 required to form a vapor deposition pattern is formed. In the vapor deposition mask according to the second implementation, one through-hole 15 in the metal layer overlaps with all the openings required to form a vapor deposition pattern.

In the vapor deposition mask according to the second implementation, the metal layer 10 may further have another through-hole that does not overlap with any openings required to form a vapor deposition pattern. In the vapor deposition mask according to the second implementation, the resin mask 20 may have an opening that is not required to form a vapor deposition pattern at a location where the opening does not overlap with the through-hole 15 in the metal layer that overlaps with all the openings required to form a vapor deposition pattern. FIGS. 8 and 9 are front views of an example of the vapor deposition mask according to the second implementation viewed in plan from the side of the metal layer.

In the vapor deposition mask 100 according to the second implementation, the metal layer 10 having one through-hole 15 is provided on the resin mask 20 having a plurality of openings 25, and all the openings 25 required to form a vapor deposition pattern are arranged at locations where the openings 25 overlap with the one through-hole 15 in the metal layer. In the vapor deposition mask 100 according to the second implementation configured in this way, the metal layer 10 does not exist between the openings 25, and therefore, the interference from the metal layer 10 described above with regard to the vapor deposition mask according to the first implementation does not occur, and a vapor deposition pattern can be accurately formed according to the dimensions of the openings 25 formed in the resin mask 20.

With the vapor deposition mask according to the second implementation, even if the thickness of the metal layer 10 is increased, there is little influence of shadows. Therefore, the thickness of the metal layer 10 can be increased until adequate durability and ease of handling are achieved. That is, the durability and the ease of handling can be improved while allowing formation of a precise vapor deposition pattern.

The resin mask 20 of the vapor deposition mask according to the second implementation is made of a resin and has a plurality of openings 25 required to form a vapor deposition pattern formed at locations where the openings 25 overlap with the one through-hole 15 in the metal layer as shown in FIGS. 8 and 9. The openings 25 correspond to the pattern to be fabricated by vapor deposition, and the vapor deposition material emitted from the vapor deposition material source passes through the opening 25 to form the vapor deposition pattern corresponding to the openings 25 on the vapor deposition target. Although the illustrated implementation is being described with regard to an example in which a plurality of openings is arranged in the longitudinal direction and the lateral direction, a plurality of openings may be arranged only one of the longitudinal direction and the lateral direction.

The “screen” in the vapor deposition mask 100 according to the second implementation refers to a set of openings 25 for one product. If the product is an organic EL display, the “screen” is a set of organic layers required for one organic EL display. That is, the “screen” is a set of openings 25 to form the organic layers of one organic EL display. The vapor deposition mask according to the second implementation may include only one screen or include a plurality of screens. When the vapor deposition mask includes a plurality of screens, the openings 25 in different screens are preferably arranged at a predetermined distance (see FIG. 4 showing the vapor deposition mask according to the first implementation). The implementation of the screen is not particularly limited. For example, provided that one opening 25 provides one pixel, one screen may be formed by a several millions of openings 25.

The metal layer 10 of the vapor deposition mask 100 according to the second implementation has one through-hole 15. In the vapor deposition mask 100 according to the second implementation, in the front view of the metal layer 10, the one through-hole 15 overlaps with all the openings 25 required to form a vapor deposition pattern. In other words, the one through-hole 15 in the metal layer is arranged at a location where the through-hole 15 allows a view of all the openings 25 in the resin mask 20 that are required to form a vapor deposition pattern.

The metal part of the metal layer 10, that is, the part of the metal layer 10 other than the one through-hole 15, may be provided along the outer edge of the vapor deposition mask 100 as shown in FIG. 8. Alternatively, as shown in FIG. 9, the metal layer 10 may have a smaller size than the resin mask 20 so that the outer peripheral part of the resin mask 20 is exposed. Alternatively, the metal layer 10 may have a larger size than the resin mask 20 so that the metal part partially protrudes outward beyond the resin mask in the lateral direction or longitudinal direction. Note that, in any case, the size of the one through-hole 15 in the metal layer is smaller than the size of the resin mask 20.

A lateral width (W1) and a longitudinal width (W2) of the metal part forming the wall of the one through-hole 15 in the metal layer 10 shown in FIG. 8 are not particularly limited and can be appropriately determined in view of the durability and the ease of handling. The width can be appropriately set at any value according to the thickness of the metal layer 10. For example, however, both the widths W1 and W2 preferably fall within a range from 1 mm to 100 mm inclusive, as with the metal layer of the vapor deposition mask according to the first implementation.

<Vapor Deposition Mask According to Third Implementation>

In a vapor deposition mask according to a third implementation, as shown in FIGS. 16 to 26, a metal layer 10 is provided on a part of one face of a resin mask 20 in which a plurality of openings 25 required to form a vapor deposition pattern is formed. With the vapor deposition mask according to the third implementation, when the vapor deposition mask is fixed to a frame, a stress that can occur in the resin mask 20 can be appropriately relieved, and as a result, a deformation, such as a stretch or a shrinkage, can be effectively inhibited.

In the vapor deposition mask according to the third implementation, the location where the metal layer 10 is provided and the two-dimensional shape of the metal layer in planar view are not particularly limited. That is, the two-dimensional shape of the metal layer 10 can be appropriately designed according to the location where the metal layer is provided.

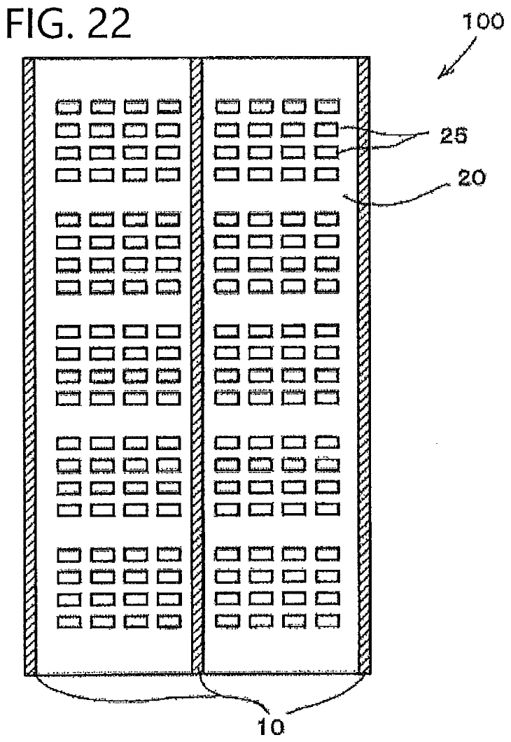

For example, as shown in FIG. 16A, when the resin mask 20 has the shape of a quadrilateral having long sides and short sides, such as a rectangle, in planar view of the vapor deposition mask 100 according to the third implementation viewed from the side of the resin mask 20, the metal layer 10 may have the shape of a band extending along the sides of the resin mask. For example, the metal layer 10 may have the shape of a band having the same length as the short sides of the resin mask and be arranged in parallel to the short sides of the resin mask 20. Alternatively, as shown in FIG. 22, when the resin mask 20 has the shape of a rectangle having long sides and short sides in planar view of the vapor deposition mask 100 according to the third implementation viewed from the side of the resin mask 20, the metal layer 10 may have the shape of a band having the same length as the long sides of the resin mask and be arranged in parallel to the long sides of the resin mask 20. Alternatively, the metal layer may have the shape of a band and be arranged at a predetermined angle with respect to the long sides of the resin mask. The quadrilateral is not limited to the rectangle but may be a trapezoid or a parallelogram, for example. Other quadrilaterals are also possible. Alternatively, the resin mask 20 may have a shape other than the quadrilateral in planar view. Even when the resin mask 20 has a shape other than the quadrilateral in planar view, the shapes and arrangement of the metal layer 10 described in this specification can be appropriately applied.

In the configuration shown in FIG. 16, six band-shaped metal layers 10 are arranged in parallel to the short sides of the resin mask 20. In the configuration shown in FIG. 22, three band-shaped metal layers 10 are arranged in parallel to the long sides of the resin mask 20. However, the number of metal layers 10 arranged is not limited. For example, although not shown, only any one of these pluralities of metal layers 10 may be arranged.

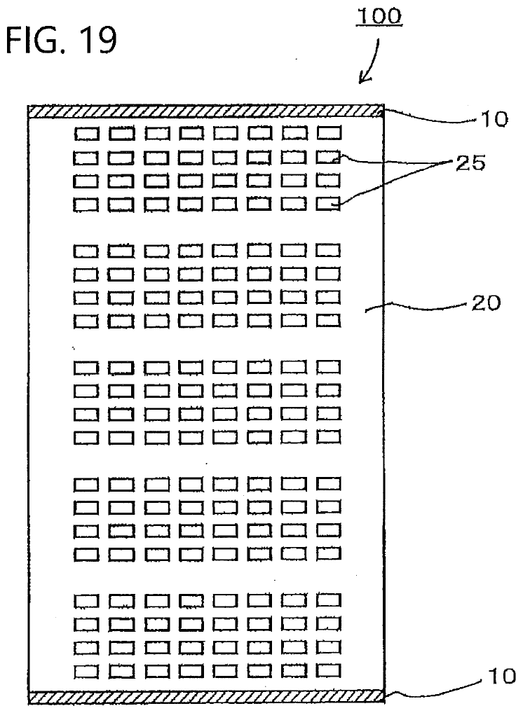

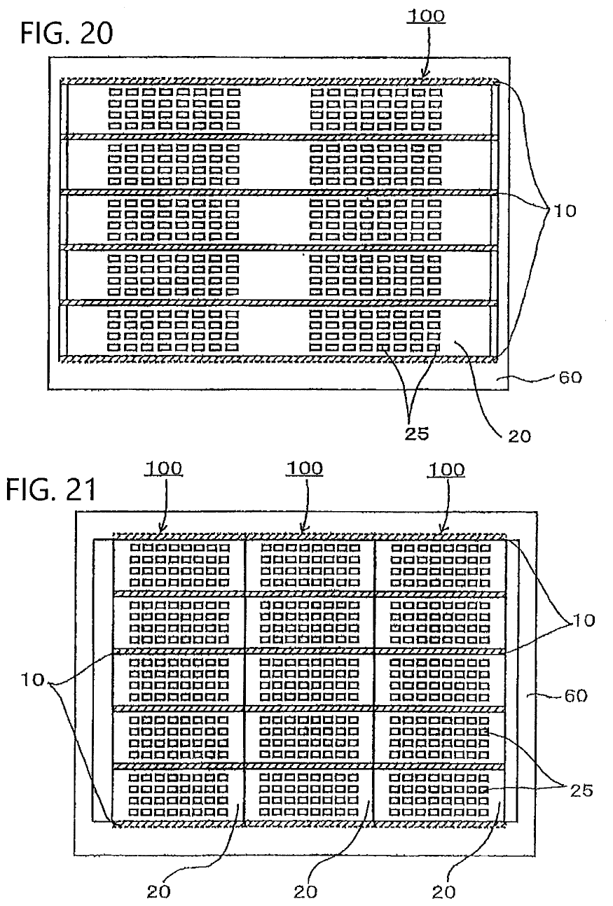

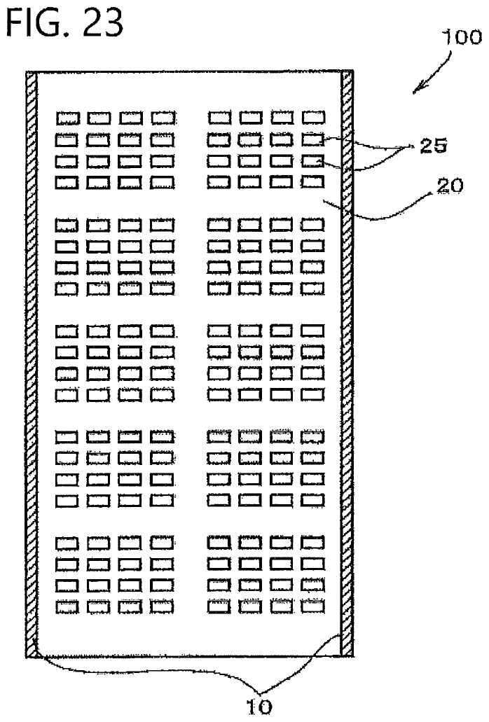

Alternatively, as shown in FIG. 19, band-shaped metal layers 10 having the same length as the short sides of the resin mask 20 may be arranged in the vicinities of the top side and the bottom side of the resin mask 20. Alternatively, as shown in FIG. 23, band-shaped metal layers 10 having the same length as the long sides of the resin mask 20 may be arranged in the vicinities of the left side and the right side of the resin mask 20. Alternatively, the metal layers 10 may have a length shorter than the long sides of the resin mask 20. In the vapor deposition masks 100 having the configurations shown in FIGS. 19 and 23, the metal layers 10 in the vicinities or the top side and the bottom side of the resin mask or in the vicinities of the left side and the right side of the resin mask are arranged in locations where the metal layers 10 overlap with the circumference of the resin mask 20. However, the metal layers 10 may be arranged at locations where the metal layers 10 do not overlap with the circumference of the resin mask 20. In addition, the metal layers 10 may be arranged only on the circumference of the resin mask 20. The circumference of the resin mask 20 referred to in this specification means a region of the resin mask 20 that overlaps with a frame member of a frame in the thickness direction when the vapor deposition mask is fixed to the frame. The region varies with the size of the frame or the width of the frame member of the frame, for example. For example, in the configuration shown in FIG. 16, only one metal layer 10 may be arranged in the vicinity of any one of the top side and the bottom side of the resin mask, or metal layers 10 may be arranged in the vicinities of both the top side and the bottom side of the resin mask. In such cases, the metal layer(s) 10 may be arranged to overlap with the circumference of the resin mask. Alternatively, instead of the band-shaped metal layers 10 having the same length as the long sides or short sides of the resin mask 20, one metal layer having a length different from the length of the long sides or short sides of the resin mask 20 may be arranged in parallel to the long sides or short sides of the resin mask 20, or a plurality of metal layers having a length different from the length of the long sides or short sides of the resin mask 20 may be arranged in parallel to the long sides or short sides of the resin mask 20. Alternatively, one or more band-shaped metal layers 10 may be arranged in a random direction.

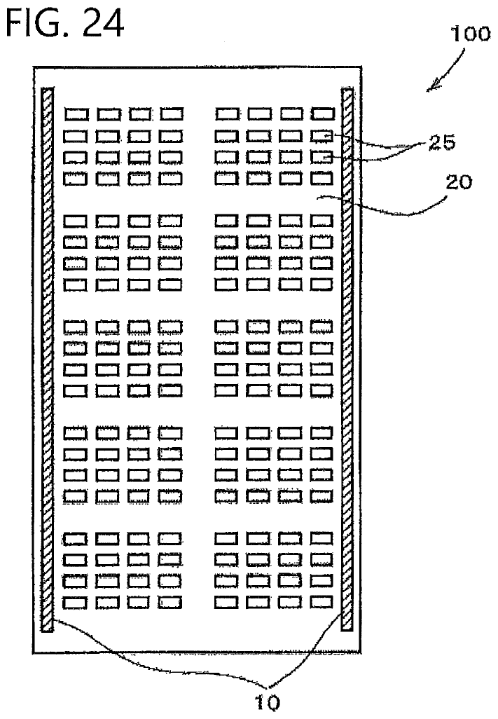

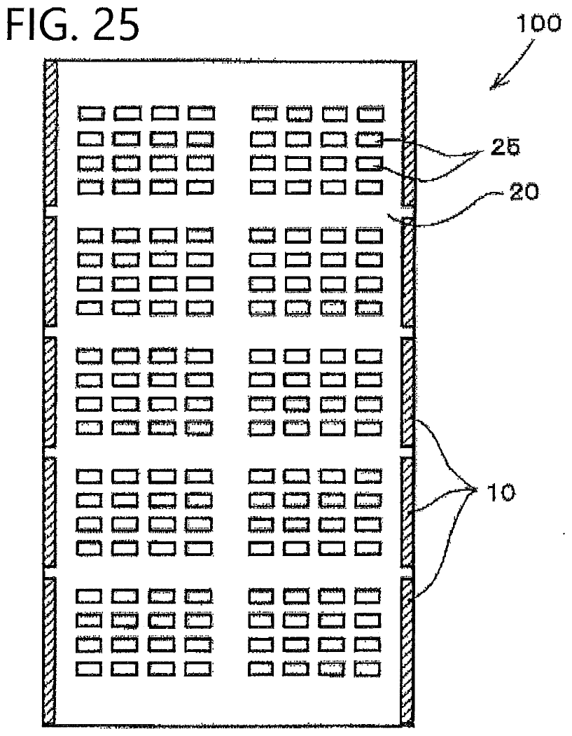

For example, as shown in FIG. 24, band-shaped metal layers 10 having a length shorter than the left and right sides or, in other words, long sides of the resin mask 20 may be arranged at locations spaced apart from the circumferential edges of the left and right sides of the resin mask 20. The regions in which the metal layers 10 are arranged in FIG. 24 may be circumferential parts of the resin mask 20 or non-circumferential parts of the resin mask 20. Alternatively, the regions may be regions extending over both the circumferential part and the non-circumferential part. Note that the non-circumferential part of the resin mask 20 referred to in this specification means the whole of the other region of the resin mask 20 than the circumferential part described above. In other words, the non-circumferential part refers to a region that does not overlap with the frame member of the frame in the thickness direction when the vapor deposition mask is fixed to the frame. Alternatively, as shown in FIG. 25, the band-shaped metal layers 10 arranged in parallel to the long sides of the resin mask 20 may be divided into a plurality of sections, five sections in FIG. 25, in the length direction thereof.

By arranging band-shaped metal layers 10 in parallel to the long sides or short sides of the resin mask 20 as described above, a deformation, such as a stretch or a shrinkage, of the resin mask 20 in the length direction of the band-shaped metal layers 10 can be effectively inhibited, and occurrence of creases can be inhibited when the vapor deposition mask 100 is fixed to the frame. Therefore, when the resin mask 20 has long sides and short sides, the metal layer 10 is preferably arranged in parallel to the long sides, which more significantly varies in length because of stretch or shrinkage.

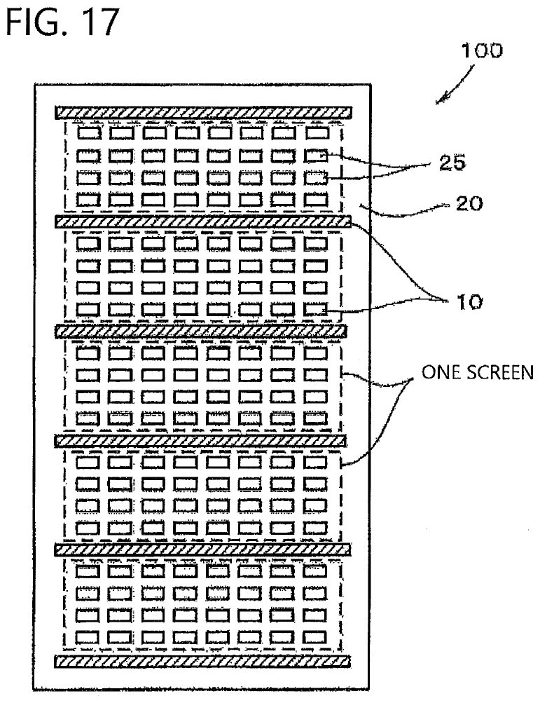

FIG. 17 is a front view of an example of the vapor deposition mask according to the third implementation viewed in plan from the side of the metal layer 10.

The metal layer 10 does not necessarily have to be located on the circumferential part of the resin mask 20. FIG. 17 shows an example in which metal layers 10 are located only on the non-circumferential part of the resin mask 20. Alternatively, the metal layers 10 may be arranged on the circumferential part and the non-circumferential part of the resin mask 20.

If the metal layers 10 are also arranged in the non-circumferential part of the resin mask 20 or, more specifically, in locations where the metal layers 10 do not overlap with the part of the resin mask 20 that does not overlap with the frame, the metal layers 10 are not only used for fixing to the frame but can also effectively inhibit a possible deformation, such as a stretch or a shrinkage, of the resin mask 20. In addition, if the metal layers 10 have the shape of a band, when the vapor deposition mask is fixed to the frame, a stress that can occur in the resin mask 20 can be appropriately relieved compared with the case where the metal layer surrounds the openings 25 formed in the resin mask 20, and as a result, a deformation, such as a stretch or a shrinkage, can be effectively inhibited.

The dotted lines shown in FIG. 17 indicate regions of screens. When the metal layers 10 are arranged on the non-circumferential part, a metal layer 10 may be arranged between screens.

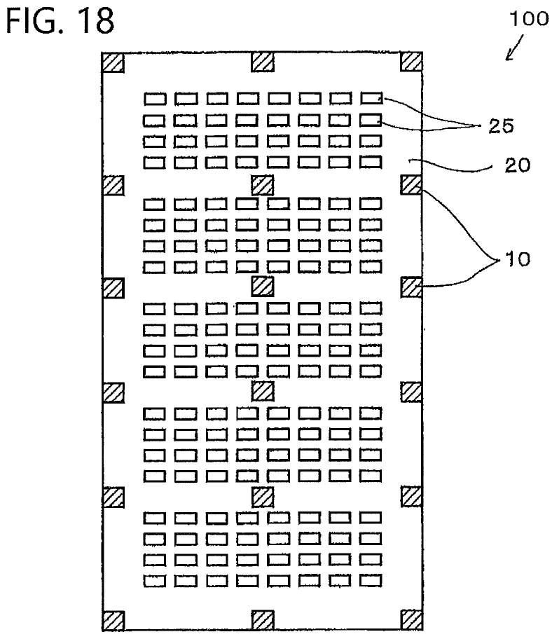

FIG. 18 is a front view of an example of the vapor deposition mask according to the third implementation viewed in plan from the side of the metal layers formed.

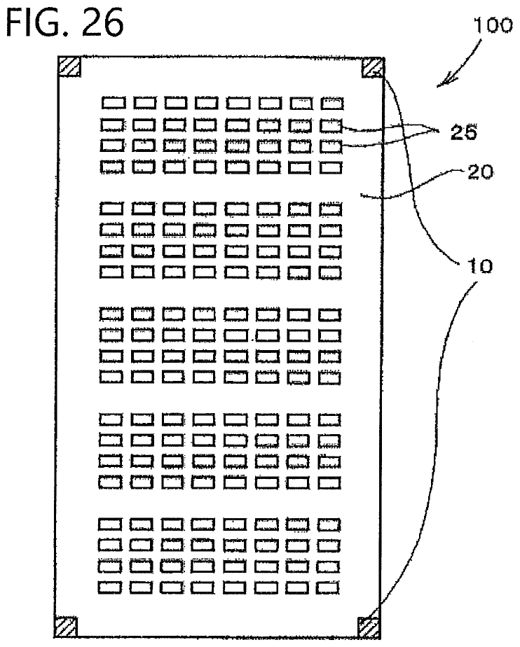

As shown in FIG. 18, the metal layers 10 do not necessarily have to be band-shaped and may be interspersed on the resin mask 20. Furthermore, as shown in FIG. 26, the metal layers 10 may be arranged only at four corners of the resin mask 20. In these cases, although the metal layers 10 shown in FIGS. 18 and 26 have a square shape, the embodiments of the present invention are not limited thereto. The metal layers 10 may have any shape, such as a triangular shape, a rectangular or other polygonal shape, a circular shape, an elliptic shape, a semicircular shape, a toroidal shape, a C-shape, a T-shape, the shape of a cross, or the shape of a star. When a plurality of metal layers 10 is provided on one resin mask 20, all the metal layers 10 do not have to have the same shape, and the metal layers 10 may have different shapes, such as those listed above. Some of the shapes and arrangements of the metal layers 10 described above can be appropriately combined with each other. In such cases, as in the case where the metal layers 10 have the shape of a band, a stress that can occur in the resin mask when the vapor deposition mask is fixed to the frame can be relieved.

As shown in FIGS. 16A, 17, 19, 20, and the like, in the vapor deposition masks 100 having preferable configurations, band-shaped metal layers 10 are arranged on the resin mask 20. In the vapor deposition masks having more preferable configurations, band-shaped metal layers 10 are arranged along the direction of conveyance of the vapor deposition mask 100 during vapor deposition. In other words, in the vapor deposition masks 100 having more preferable configurations, band-shaped metal layers 10 are arranged on the resin mask 20 along the direction perpendicular to the linear source (vapor deposition material source) used for vapor deposition. For example, provided that the left-to-right direction in the drawing is the direction of conveyance of the vapor deposition mask, as shown in FIGS. 16A, 17, 19, and the like, the vapor deposition mask 100 preferably has band-shaped metal layers 10 arranged along the direction of conveyance. With the vapor deposition mask 100 having such a configuration, occurrence of a variation in dimension or position of the openings 25 formed in the resin mask 20 can be more effectively inhibited.

The thickness of the metal layer 10 is not particularly limited. However, in order to more effectively prevent occurrence of a shadow, the thickness is preferably equal to or smaller than 100 μm, more preferably equal to or smaller than 50 μm, or most preferably equal to or smaller than 35 μm. If the metal layer 10 has such a thickness, the risk of breakage or deformation can be reduced, and the ease of handling can be improved.

In the configuration shown in FIG. 1B, the through-hole part 15 of the metal layer 10 has a rectangular-shape when viewed in plan from the side of the metal layer 10, the through-hole part 15 may have any shape, such as a trapezoidal shape or a circular shape.

The cross-sectional shape of the metal layer 10 is also not particularly limited. However, as shown in FIG. 1B, the metal layer 10 preferably has a cross-sectional shape that expands as it goes toward the vapor deposition material source. More specifically, the angle formed by the inner wall face of the metal layer 10 and the face of the metal layer 10 closer to the resin mask 20 (the upper face of the metal layer in the drawing) preferably falls within a range from 5° to 85° inclusive, more preferably falls within a range from 15° to 80° inclusive, and still more preferably falls within a range from 25° to 65° inclusive. Among these ranges, in particular, the angle is preferably smaller than the vapor deposition angle of the vapor deposition machine used.

The method of providing the metal layer 10 on the resin mask is not particularly limited, and the resin mask 20 and the metal layer 10 may be bonded to each other with various kinds of adhesives, or a resin mask having adhesion may be used. The metal layer 10 can be formed in various methods described later with regard to a method of manufacturing a vapor deposition mask according to an embodiment of the present disclosure, such as etching or plating. Alternatively, a laminated body including a resin plate (including a resin layer) to form the resin mask and a metal plate to form the metal layer may be prepared, and the laminated body may be processed to form the resin mask 20 and the metal layer 10. The resin mask 20 and the metal layer 10 may have the same size or different sizes. Note that, considering that the vapor deposition mask may optionally be fixed to a frame, it is preferable that the resin mask 20 is smaller than the metal layer 10 so that the outer peripheral part of the metal layer 10 is exposed, since the metal layer 10 can be easily fixed to the frame.

A groove (not shown) extending in the longitudinal direction or lateral direction of the resin mask 20 may be formed in the resin mask 20. When heat is applied during vapor deposition, the resin mask 20 can thermally expand and cause a variation in dimension or position of the opening 25. However, if the groove is formed, the groove can accommodate the expansion of the resin mask and prevent the resin mask 20 from expanding in a predetermined direction as a whole because of accumulation of local thermal expansions of the resin mask and causing a variation in dimension or position of the opening 25. The location where the groove is formed is not limited, and the groove can be provided at any location, such as between openings 25 forming one screen, a location where the groove overlaps with the through-hole 15 in the metal layer, or a location where the groove does not overlap with the through-hole 15 in the metal layer. However, the groove is preferably provided between screens. The groove may be provided only on the face of the resin mask on the side of the metal layer 10 or only on the face of the resin mask 20 opposite to the metal layer. The groove may be provided on both faces of the resin mask 20.

A groove extending in the longitudinal direction between adjacent screens or a groove extending in the lateral direction between adjacent screens may be formed. Furthermore, a combination of such grooves may be formed.

The depth and width of the groove are not particularly limited and can be appropriately determined by considering the rigidity of the resin mask 20. The cross-sectional shape of the groove is also not particularly limited, and any shape, such as a U-shape or a V-shape, can be chosen by considering the processing method.

(Frame-Equipped Vapor Deposition Mask)

A frame-equipped vapor deposition mask 200 according to an embodiment of the present disclosure includes the vapor deposition mask 100 according to any of the implementations of the present disclosure described above that is fixed to a frame 60. Descriptions of the vapor deposition mask 100 will be omitted.

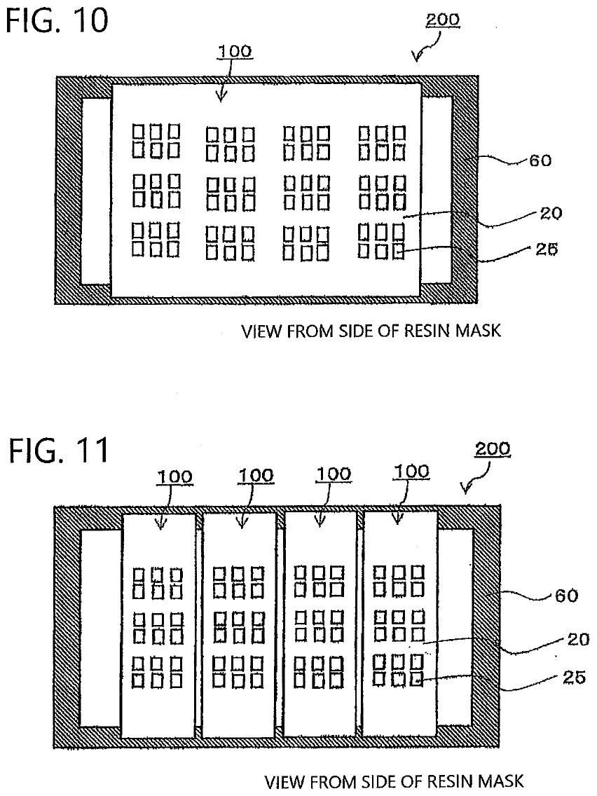

The frame-equipped vapor deposition mask 200 may include one vapor deposition mask 100 fixed to the frame 60 as shown in FIG. 10 or include a plurality of vapor deposition masks 100 fixed to the frame 60 as shown in FIG. 11.

For example, as shown in FIG. 20, one vapor deposition mask 100 including a plurality of vapor deposition masks integrated with each other may be fixed to the frame 60. Note that, in the configuration shown in FIG. 20, the whole or a part of the edge parts of each metal layer 10 extending in the longitudinal direction is in contact with the frame (the whole of the edge parts of all the metal layers 10 extending in the longitudinal direction is in contact with the frame 60 in the illustrated configuration), and the metal layers 10 are fixed to the frame not only at the parts in the vicinities of the top side and the bottom side of the vapor deposition masks 100 but also a part or the whole of the edge parts of the metal layers 10. The metal layer 10 may be configured so that the edge parts extending in the longitudinal direction is not in contact with the frame 60, and the vapor deposition mask 100 may be fixed to the frame at the parts of the metal layer 10 in the vicinities of the top side and bottom side of the vapor deposition mask 100.

Alternatively, as shown in FIG. 21, three or more vapor deposition masks 100 may be arranged side by side (three vapor deposition masks are arranged in the illustrated configuration). In this case, the plurality of vapor deposition masks 100 may be arranged with or without a clearance between the adjacent vapor deposition masks 100 (the three vapor deposition masks are arranged without a clearance in the configuration shown in FIG. 21). In addition, in the configuration shown in FIG. 21, of the vapor deposition masks 100 fixed to the frame, edge parts of the metal layers 10 of the vapor deposition masks 100 located at the opposite ends in the longitudinal direction are not in contact with the frame. However, the edge parts of the metal layers 10 of the vapor deposition masks 100 located at the opposite ends in the longitudinal direction may be in contact with the frame (not shown).

The frame 60 is a frame member having a substantially rectangular shape and has a through-hole that allows the openings 25 formed in the resin mask 20 of the vapor deposition mask 100 that is to be finally fixed to the frame 60 to be exposed on the side of the vapor deposition material source. The material of the frame may be a metal material, a glass material or a ceramic material, for example.

The thickness of the frame is also not particularly limited. However, from the viewpoint of rigidity or the like, the thickness of the frame preferably falls within a range from 10 mm to 100 mm inclusive, or more preferably falls within a range from 10 mm to 30 mm inclusive. The width between the inner peripheral edge face of the frame and the outer peripheral edge face of the frame is not particularly limited as far as the width allows fixing of the metal layer of the vapor deposition mask to the frame. For example, the width falls within a range from 10 mm to 300 mm inclusive or a range from 10 mm to 70 mm inclusive.

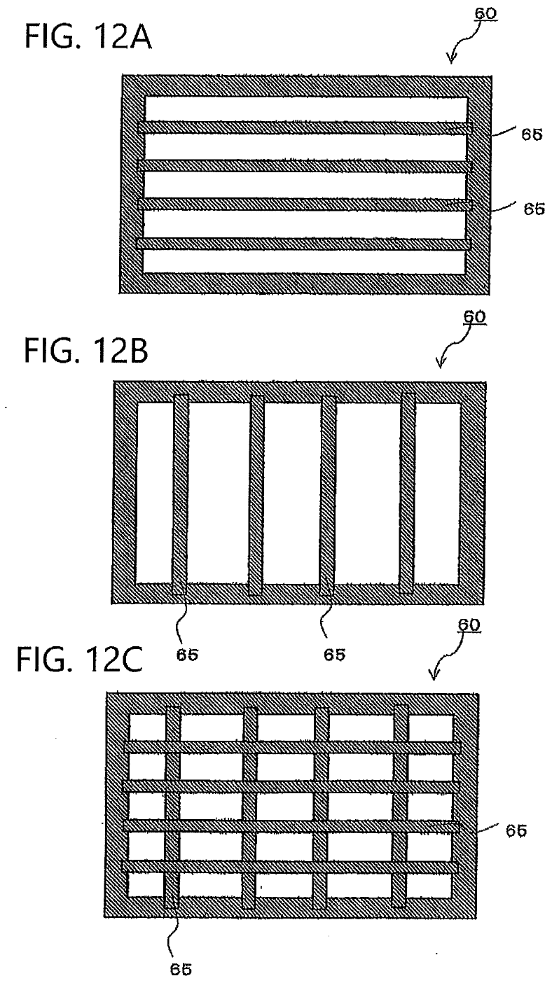

As shown in FIGS. 12A to 12C, the frame 60 may be provided with a reinforcing frame 65 or the like in the region of the through-hole of the frame. In other words, the opening of the frame 60 may be divided by a reinforcing frame or the like. When the reinforcing frame 65 is provided, the reinforcing frame 65 can be used to fix the frame 60 and the vapor deposition mask 100 to each other. Specifically, when a plurality of vapor deposition masks 100 are arranged and fixed side by side in the longitudinal direction and lateral direction as described above, the vapor deposition masks 100 can be fixed to the frame 60 at the parts where the vapor deposition masks overlap with the reinforcing frame.

The method of fixing the vapor deposition masks 100 to the frame 60 is also not particularly limited. The vapor deposition masks 100 can be fixed to the frame 60 by spot welding using laser light or the like, with an adhesive or a screw, or in any other method.

<<Vapor Deposition Mask Preparation Body>>

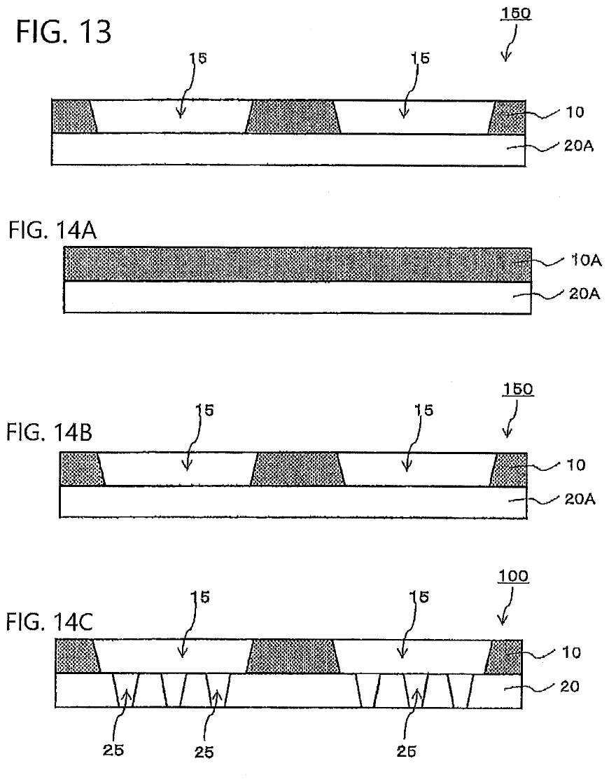

As shown in FIG. 13, a vapor deposition mask preparation body according to an embodiment of the present disclosure is a vapor deposition mask preparation body 150 from which a vapor deposition mask including a resin mask 20 having an opening 25 required to form a vapor deposition pattern and a metal layer 10 provided on the resin mask 20, and includes a metal layer 10 provided on a resin plate 20A. With the vapor deposition mask preparation body 150 according to the embodiment of the present disclosure, the resin plate 20A contains a resin material, the metal layer 10 contains a metal material, and in a linear expansion graph whose vertical axis indicates linear expansion rate and whose horizontal axis indicates temperature, provided that the glass transition temperature (Tg) of the resin material plus 100° C. is an upper limit temperature, the integrated value of the linear expansion curve for the resin plate over a range from a temperature of 25° C. to the upper limit temperature divided by the integrated value of the linear expansion curve for the metal layer over the range from the temperature of 25° C. to the upper limit temperature is defined to fall within a range from 0.55 to 1.45 inclusive.

With the vapor deposition mask preparation body 150 according to the embodiment of the present disclosure, when the opening 25 is formed in the resin plate 20A, slack, creases or the like on the resin plate 20A and an excessive tension on the resin plate 20A can be inhibited, and the opening 25 that is precise in dimension and position and can be inhibited from varying in dimension or position can be formed. That is, with the vapor deposition mask preparation body 150 according to the embodiment of the present disclosure, a vapor deposition mask that has a precise opening 25 that can be inhibited from varying in dimension or position can be obtained.

The vapor deposition mask preparation body 150 according to the embodiment of the present disclosure is the same as the vapor deposition mask according to another embodiment of the present disclosure described above except that the resin mask 20 having the opening 25 is replaced by the resin plate 20A.

The resin plate 20A may be a resin layer obtained by various coating processes or a sheet-like resin plate. The resin plate 20A constitutes the resin mask 20 in the end, so that the thickness of the resin plate 20A can be determined based on the thickness of the resin mask 20 finally formed.

<<Method of Manufacturing Vapor Deposition Mask>>

A method of manufacturing a vapor deposition mask according to an embodiment of the present disclosure is a method of manufacturing a vapor deposition mask including a resin mask 20 having an opening 25 required to form a vapor deposition pattern and a metal layer 10 provided on the resin mask 20, and includes a step of providing a resin plate 20A containing a resin material on a metal plate 10A containing a metal material (see FIG. 14A), a step of processing the metal plate 10A to form a metal layer 10 on the resin plate 20A (see FIG. 14B), and a step of forming an opening 25 in the resin plate 20A (see FIG. 14C). As for the resin plate containing a resin material and the metal plate containing a metal material used in the method of manufacturing a vapor deposition mask according to the embodiment of the present disclosure, in a linear expansion graph whose vertical axis indicates linear expansion rate and whose horizontal axis indicates temperature, provided that the glass transition temperature (Tg) of the resin material plus 100° C. is an upper limit temperature, the integrated value of the linear expansion curve for the resin plate over a range from a temperature of 25° C. to the upper limit temperature divided by the integrated value of the linear expansion curve for the metal layer over the range from the temperature of 25° C. to the upper limit temperature is defined to fall within a range from 0.55 to 1.45 inclusive.

A method of manufacturing a vapor deposition mask according to another embodiment of the present disclosure is a method of manufacturing a vapor deposition mask including a resin mask 20 having an opening 25 required to form a vapor deposition pattern and a metal layer 10 provided on the resin mask 20, and includes a step of providing the metal layer 10 on a resin plate 20A containing a resin material and a step of forming the opening 25 required to form a vapor deposition pattern in the resin plate 20A. As for the resin plate containing a resin material and the metal layer containing a metal material used in the method of manufacturing a vapor deposition mask according to the embodiment of the present disclosure, in a linear expansion graph whose vertical axis indicates linear expansion rate and whose horizontal axis indicates temperature, provided that the glass transition temperature (Tg) of the resin material plus 100° C. is an upper limit temperature, the integrated value of the linear expansion curve for the resin plate over a range from a temperature of 25° C. to the upper limit temperature divided by the integrated value of the linear expansion curve for the metal layer over the range from the temperature of 25° C. to the upper limit temperature is defined to fall within a range from 0.55 to 1.45 inclusive.

With the methods of manufacturing a vapor deposition mask according to the embodiments of the present disclosure, when the opening 25 is formed in the resin plate 20A, slack, creases or the like on the resin plate 20A and an excessive tension on the resin plate 20A can be inhibited, and the opening 25 that is precise in dimension and position and can be inhibited from varying in dimension or position can be formed. That is, with the methods of manufacturing a vapor deposition mask according to the embodiments of the present disclosure, a vapor deposition mask that has a precise opening 25 that can be inhibited from varying in dimension or position can be obtained.

(Step of Providing Resin Plate on Metal Plate)

This step is a step of providing the resin plate 20A on the metal plate 10A containing a metal material as shown in FIG. 14A.

As for the resin plate 20A containing a resin material and the metal plate 10A containing a metal material used in the method of manufacturing a vapor deposition mask according to the embodiment of the present disclosure, in a linear expansion graph whose vertical axis indicates linear expansion rate and whose horizontal axis indicates temperature, provided that the glass transition temperature (Tg) of the resin material plus 100° C. is an upper limit temperature, the integrated value of the linear expansion curve for the resin mask over a range from a temperature of 25° C. to the upper limit temperature divided by the integrated value of the linear expansion curve for the metal layer over the range from the temperature of 25° C. to the upper limit temperature is defined to fall within a range from 0.55 to 1.45 inclusive.

The resin plate 20A may be previously molded or may be formed by applying a coating liquid containing the resin material to the metal plate 10A and drying the coating liquid. Alternatively, the resin plate 20A (which may be a resin film or a resin sheet) may be bonded to the metal plate 10A with an adhesive layer or the like interposed therebetween. The coating liquid used to form the resin plate 20A contains the resin material and a medium in which the resin material is dissolved. The method of applying the coating liquid is not particularly limited and can be a well-known process, such as gravure printing, screen printing, or reverse roll coating using a gravure plate. The amount of the coating liquid applied can be appropriately determined based on the thickness of the resin mask 20 finally obtained.

The metal plate 10A may be bonded to the resin plate 20A with a cohesive layer or adhesive layer interposed therebetween.

The resin material is not particularly limited, and any resin material described above as being contained in the resin mask 20 with regard to the vapor deposition mask according to the embodiment of the present disclosure can be appropriately selected and used. For example, the resin plate 20A may include a cured thermosetting resin. The resin plate 20A including a cured thermosetting resin can be obtained by applying a coating liquid containing the thermosetting resin to the metal plate 10A and heating the coating liquid at a temperature higher than the setting temperature of the thermosetting resin. The temperature at which the thermosetting resin is cured can be appropriately determined for the particular thermosetting resin contained in the resin plate 20A. Note that when the resin plate 20A contains a plurality of thermosetting resins, the coating liquid is preferably heated at a temperature higher than the highest setting temperature of the setting temperatures of the plurality of thermosetting resins.

(Step of Providing Metal Layer)

This step is a step of processing the metal plate 10A with the resin plate 20A formed on the surface thereof to form the metal layer 10 as shown in FIG. 14B. Although in the illustrated configuration, the metal plate 10A is processed to provide a metal layer 10 having a plurality of through-holes 15, the metal plate 10A may be processed to provide a metal layer 10 having one through-hole 15 or a plurality of metal layers 10 located on parts of the resin plate 20A. The method of forming the metal layer 10 is not particularly limited, and a conventionally well-known process, such as laser processing, etching, or machine processing, can be used. For example, when the metal layer 10 is formed by etching, a resist material is applied to a surface of the metal plate 10A, masking of the resist material is performed using a mask for forming the metal layer 10, and then exposure and development are performed. A photoresist material may be applied to a surface of each of the metal plate 10A and the resin plate 20A. A dry film process may be used in which a dry film resist is applied instead of applying the photoresist material. Then, using the resist pattern as an etching mask, only the metal plate 10A is etched, and the resist pattern is removed by washing after the etching. In this way, the metal layer 10 can be formed at a desired location on the resin plate 20A.

As an alternative to the formation of the metal layers 10 using the metal plate 10A, the metal layer 10 can also be formed by plating. An example method of forming the metal layer 10 on the resin plate 20A by plating is a method of forming the metal layer 10 on the resin plate 20A by various kinds of plating. Another example formation method is a method of forming the metal layer 10 on the resin plate 20A by forming the metal layer 10 by various kinds of plating on a support body, such as a glass substrate, bonding the formed metal layer 10 and the resin plate 20A to each other, and then peeling the metal layer 10 off the support body. Alternatively, a metal plate may be formed by various kinds of plating, and the metal plate may be processed to form the metal layer 10.

In the step of providing the metal layer described above, instead of the process of processing the metal plate 10A to form the metal layer 10, a previously prepared metal layer 10 may be provided on the resin plate 20A. For example, a previously prepared metal layer 10 may be bonded to the resin plate 20A with an adhesive or the like.

(Step of Forming Opening)

This step is a step of forming the opening 25 in the resin plate 20A containing a resin material as shown in FIG. 14C. Through this step, the vapor deposition mask 100 including the resin mask 20 having the opening 25 required to form a vapor deposition pattern and the metal layer 10 provided on the resin mask is obtained.

The metal layer 10 may be provided on the resin plate 20A after the step of forming the opening 25.

The method of forming the opening 25 is not particularly limited, and a conventionally well-known process, such as laser processing, etching, or machine processing, can be used. Note that the laser processing is preferable because the opening 25 can be more accurately formed in the resin plate 20A.

Although an example has been primarily described in which the metal layer 10 is first formed on the resin plate 20A, and the opening 25 is then formed in the resin plate 20A, the opening 25 may be first formed in the resin plate 20A, and the metal layer 10 may be then formed on the resin plate 20A (resin mask 20) having the opening 25 formed therein. For example, if the plating process described above is used, the metal layer 10 can be selectively formed on the resin mask 20 having the opening 25 formed therein without processing the metal plate 10A. Note that, considering the accuracy of the dimensions and position of the opening formed in the resin mask 20 at the time when the vapor deposition mask is fixed to the frame, the opening 25 is preferably formed after the resin plate 20A is fixed to the frame. In this case, the metal layer 10 may be formed on the resin plate 20A fixed to the frame, or the metal layer 10 may be first formed on the resin plate 20A, and the resin plate 20A with the metal layer 10 formed thereon may be then fixed to the frame. Alternatively, a stack of the resin plate 20A and the metal plate 10A may be fixed to the frame, or the metal plate 10A may be provided on the resin plate 20A fixed to the frame, and after that, the opening 25 may be formed in the resin plate 20A, and the metal layer 10 may be processed to form the metal plate 10A.

The vapor deposition mask manufactured in the method of manufacturing a vapor deposition mask according to the embodiment of the present disclosure may be the vapor deposition mask according to each implementation of the present disclosure described above.

(Vapor Deposition Method Using Vapor Deposition Mask)

The vapor deposition method used for forming a vapor deposition pattern using the vapor deposition mask according to each implementation of the present disclosure or the frame-equipped vapor deposition mask according to each implementation of the present disclosure is not particularly limited, and may be physical vapor deposition, such as reactive sputtering, vacuum deposition, ion plating, or electron beam deposition, or chemical vapor deposition, such as thermal CVD, plasma CVD, or photo CVD, for example. The vapor deposition pattern can be formed with a conventionally well-known vacuum deposition apparatus, for example.

<<Method of Manufacturing Organic Semiconductor Element>>

Next, a method of manufacturing an organic semiconductor element according to an embodiment of the present disclosure will be described. The method of manufacturing an organic semiconductor element according to the embodiment of the present disclosure includes a vapor deposition pattern formation step of forming a vapor deposition pattern on a vapor deposition target using a vapor deposition mask, and in the vapor deposition pattern formation step, the vapor deposition mask according to any of the implementations of the present disclosure described above or the frame-equipped vapor deposition mask according to any of the implementations of the present disclosure is used.

The vapor deposition pattern formation step of forming a vapor deposition pattern in a vapor deposition process using a vapor deposition mask is not particularly limited. The vapor deposition pattern formation step includes an electrode formation step of forming an electrode on a substrate, an organic layer formation step, an opposed-electrodes formation step, a sealing layer formation step and the like. In any of these steps, the vapor deposition pattern is formed in the vapor deposition pattern formation method according to the embodiment of the present disclosure described above. For example, when the vapor deposition pattern formation method according to the embodiment of the present disclosure described above is applied to a luminescent layer formation step for red (R), green (G), and blue (B) of an organic EL device, a vapor deposition pattern for a luminescent layer of each color is formed on the substrate. The method of manufacturing an organic semiconductor element according to the embodiment of the present disclosure is not limited to these steps but can be applied to any step in a conventionally well-known manufacturing process for an organic semiconductor element.

With the method of manufacturing an organic semiconductor element according to the embodiment of the present disclosure described above, vapor deposition for forming the organic semiconductor element can be performed in a state where the vapor deposition mask and the vapor deposition target are in intimate contact with each other without a clearance, and the organic semiconductor element can be accurately manufactured. The organic semiconductor element manufactured in the method of manufacturing an organic semiconductor element according to the embodiment of the present disclosure may be an organic layer, a luminescent layer, or a cathode electrode of an organic EL element, for example. In particular, the method of manufacturing an organic semiconductor element according to the embodiment of the present disclosure can be appropriately used to manufacture a red (R) luminescent layer, a green (G) luminescent layer, and a blue (B) luminescent layer of an organic EL device, which is required to have a precise pattern.

<<Method of Manufacturing Organic EL Display>>

Next, a method of manufacturing an organic electroluminescent display (organic EL display) according to an embodiment of the present disclosure will be described. The method of manufacturing an organic EL display according to the embodiment of the present disclosure uses the organic semiconductor element manufactured in the method of manufacturing an organic semiconductor element according to the embodiment of the present disclosure described above in the process of manufacturing the organic EL display.

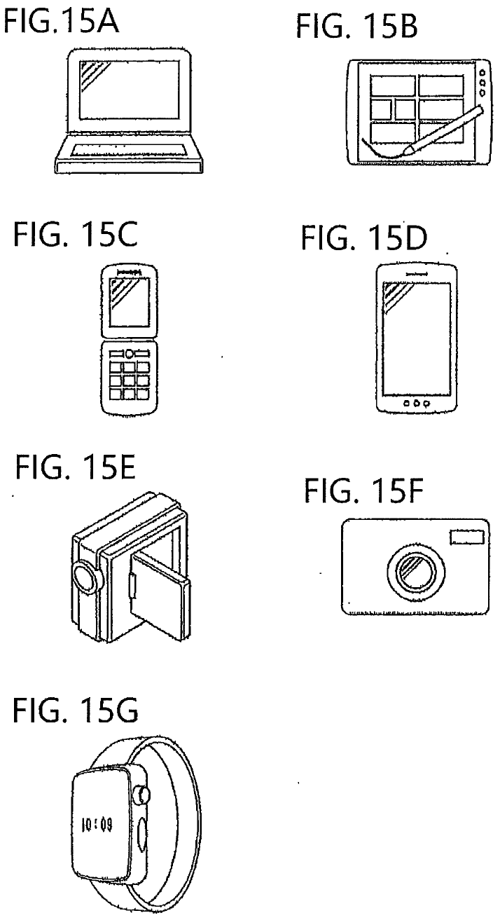

The organic EL display incorporating the organic semiconductor element manufactured in the method of manufacturing an organic semiconductor element according to the embodiment of the present disclosure may be an organic EL display used in a notebook personal computer (see FIG. 15A), a tablet terminal (see FIG. 15B), a cellular phone (see FIG. 15C), a smartphone (see FIG. 15D), a video camera (see FIG. 15E), a digital camera (see FIG. 15F), or a smart watch (see FIG. 15G), for example.

### EXAMPLES AND COMPARATIVE EXAMPLES

Nine vapor deposition mask preparation body samples A to I in which a resin plate is provided on a metal plate were prepared. For the vapor deposition mask preparation body samples A to I, the CTE curves for the metal plate and the resin plate forming the vapor deposition mask preparation body are created in the method (method of creating a linear expansion curve) described above, and the ratio is calculated by dividing the calculated integrated value for the resin mask by the calculated integrated value for the metal layer. Table 1 shows the result of the calculation of the ratio. In the table, [Resin Plate/Metal Plate] means the integrated value of the linear expansion curve for the resin plate over a range from a temperature of 25° C. to the upper limit temperature divided by the integrated value of the linear expansion curve for the metal plate over the range from the temperature of 25° C. to the upper limit temperature in the resin plate and the metal plate forming each vapor deposition mask preparation body sample.

Each vapor deposition mask preparation body sample was fabricated in the manner described below.

(Fabrication of Vapor Deposition Mask Preparation Body Sample)

A metal plate having a thickness of 20 μm was prepared, and a polyimide resin precursor (UPIA (registered trademark) ST, UBE INDUSTRIES, LTD.) was applied to one face of the metal plate with a comma coater and then dried at 130° C. for 120 seconds and then at 160° C. for 160 seconds. After the polyimide resin precursor is dried, the polyimide resin precursor was fired under the baking conditions (baking temperature and baking time) shown in Table 1 below. In this way, vapor deposition mask preparation body samples (vapor deposition mask preparation body samples A to I) in which a resin plate having a thickness of 5 μm was formed on a metal plate were prepared. The baking was performed in a nitrogen atmosphere. The metal plate used was made of Fe—36Ni alloy (invar). The resin plate (the resin plate fired under the baking conditions shown in Table 1 below) in each vapor deposition mask preparation body sample is the cured polyimide resin.

Each vapor deposition mask preparation body sample fabricated as described above was cut into a size of 100 mm (in the width direction) by 150 mm (in the length direction). The metal plate in each cut vapor deposition mask preparation body sample was etched from the side of the metal plate in the method described in Example 1 in Japanese Patent No. 3440333, and one through-hole having a size of 70 mm (in the width direction) by 120 mm (in the length direction) was formed in a central part of the metal plate in such a manner that the through-hole penetrates through only the metal plate. For each vapor deposition mask preparation body sample in which the through-hole was formed, (1) the degree of creases occurring in the resin plate was evaluated according to the evaluation method described below. Then, an opening was formed in the resin plate in each vapor deposition mask preparation body sample in which the through-hole was formed in the method described below, and (2) the variation in position of the opening was measured.

(1) Evaluation of Creases in Resin Plate

For each vapor deposition mask preparation body sample in which the through-hole was formed, the part of the resin plate visible through the through-hole was visually checked, and creases in the resin plate were evaluated according to the evaluation criterion described below. The result of the evaluation is shown in Table 1.

[Evaluation Criterion]

A: no creases that can be observed have occurred in the resin plate.

B: little creases that can be observed have occurred in the resin plate.

C: creases that can cause trouble in use have occurred in the resin plate.

(2) Measurement of Variation in Position of Opening

For each vapor deposition mask preparation body sample evaluated for creases as described above, the surface of the resin plate on the side of the metal plate was irradiated multiple times with a YAG laser (1 J/cm²) having a wavelength of 355 nm and a rectangular pattern of a size of 30 μm by 500 μm through the through-hole formed in the metal plate, thereby forming openings in two rows by two columns in the resin plate. The gap between the long sides was 5 μm, and the gap between the short sides was 50 μm. Then, the state of the openings was observed with a microscope. One bridge part (one 50-μm gap between short sides) was cut by laser. Then, the variation in position of the openings was observed on a microscope video monitor, measured and evaluated according to the evaluation criterion described below. The result of the evaluation is shown in Table 1.

[Evaluation Criterion]

A: the variation in position of opening is equal to or smaller than 2 μm.

B: the variation in position of opening is greater than 2 μm and smaller than 4 μm.

C: the variation in position of opening is equal to or greater than 4 μm.

TABLE 1

| | Conditions of Fabrication of | | | | |
|---|---|---|---|---|---|
| | Resin Plate | | Resin | | |
| | Baking | Baking | Plate/ | Evalua- | Variation in |
| | Temperature | Time | Metal | tion of | Position of |
| | (° C.) | (minutes) | Plate | Creases | Openings |
| Sample A | 400 | 1 | 1.5 | A | C |
| Sample B | 400 | 1.5 | 1.4 | A | B |
| Sample C | 400 | 2 | 1.3 | A | B |
| Sample D | 400 | 3 | 1.2 | A | A |
| Sample E | 400 | 4 | 1.0 | A | A |
| Sample F | 400 | 6 | 0.8 | A | A |
| Sample G | 400 | 8 | 0.7 | B | A |
| Sample H | 400 | 9 | 0.6 | B | A |
| Sample I | 400 | 10 | 0.5 | C | A |

### REFERENCE SIGNS LIST

10A metal plate
10 metal layer
15 through-hole in metal layer
20A resin plate
20 resin mask
25 opening
60 frame
100 vapor deposition mask
150 vapor deposition mask preparation body

1. A vapor deposition mask in which a metal layer is provided on a resin mask,
wherein the resin mask has an opening required to form a vapor deposition pattern,
the resin mask contains a resin material,
the metal layer contains a metal material, and
provided that a glass transition temperature (Tg) of the resin material plus 100° C. is an upper limit temperature,
in a linear expansion graph whose vertical axis indicates linear expansion rate and whose horizontal axis indicates temperature, an integrated value of a linear expansion curve for the resin mask over a range from a temperature of 25° C. to the upper limit temperature divided by an integrated value of a linear expansion curve for the metal layer over the range from the temperature of 25° C. to the upper limit temperature falls within a range from 0.55 to 1.45 inclusive.

2. The vapor deposition mask according to claim 1, wherein the resin material is a cured polyimide resin.

3. The vapor deposition mask according to claim 1, wherein the metal material is an iron alloy.

4. A frame-equipped vapor deposition mask in which a vapor deposition mask is fixed to a frame,
wherein the vapor deposition mask is the vapor deposition mask according to claim 1.

5. A vapor deposition mask preparation body from which a vapor deposition mask in which a metal layer is provided on a resin mask is derived,
wherein a metal layer is provided on a resin plate,
the resin plate contains a resin material,
the metal layer contains a metal material, and
provided that a glass transition temperature (Tg) of the resin material plus 100° C. is an upper limit temperature,
in a linear expansion graph whose vertical axis indicates linear expansion rate and whose horizontal axis indicates temperature, an integrated value of a linear expansion curve for the resin plate over a range from a temperature of 25° C. to the upper limit temperature divided by an integrated value of a linear expansion curve for the metal layer over the range from the temperature of 25° C. to the upper limit temperature falls within a range from 0.55 to 1.45 inclusive.

6. The vapor deposition mask preparation body according to claim 5, wherein the resin material is a cured polyimide resin.

7. The vapor deposition mask preparation body according to claim 5, wherein the metal material is an iron alloy.

8. A method of manufacturing a vapor deposition mask in which a metal layer is provided on a resin mask, comprising:
a step of providing a metal layer containing a metal material on a resin plate containing a resin material; and
a step of forming an opening required to form a vapor deposition pattern in the resin plate,
wherein the metal layer is provided on the resin plate in such a manner that, provided that a glass transition temperature (Tg) of the resin material plus 100° C. is an upper limit temperature,
in a linear expansion graph whose vertical axis indicates linear expansion rate and whose horizontal axis indicates temperature, an integrated value of a linear expansion curve for the resin mask over a range from a temperature of 25° C. to the upper limit temperature divided by an integrated value of a linear expansion curve for the metal layer over the range from the temperature of 25° C. to the upper limit temperature falls within a range from 0.55 to 1.45 inclusive.

9. The method of manufacturing a vapor deposition mask according to claim 8, wherein the resin plate includes a cured polyimide resin.

10. A method of manufacturing an organic semiconductor element,
wherein the vapor deposition mask according to claim 1 is used.

11. A method of manufacturing an organic EL display,
wherein the organic semiconductor element manufactured in the method of manufacturing an organic semiconductor element according to claim 10 is used.

12. A method of forming a pattern fabricated by vapor deposition,
wherein the vapor deposition mask according to claim 1 is used.
